(19) United States
(12) Patent Application Publication
(10) Pub. No.: US 2026/0282351 A1
(43) Pub. Date: Sep. 17, 2026

(54) SEMICONDUCTOR MEMORY DEVICE

(71) Applicant: Kioxia Corporation, Tokyo (JP)

(72) Inventors: Tatsuya KATO, Yokkaichi Mie (JP); Satoshi NAGASHIMA, Yokkaichi Mie (JP); Akira MINO, Yokkaichi Mie (JP)

(73) Assignee: Kioxia Corporation, Tokyo (JP)

(21) Appl. No.: 19/274,755

(22) Filed: Jul. 21, 2025

(30) Foreign Application Priority Data
Mar. 12, 2025 (JP) 2025-039333

(51) Int. Cl. H10B 43/27; H10B 43/10

(52) U.S. Cl. CPC H10B 43/27; H10B 43/10

(57) ABSTRACT

A semiconductor memory device comprises: memory cells arranged in a first direction; conductive layers connected to memory cells; and a contact electrode. The contact electrode includes: a connecting portion connected to a first conductive layer; and an extending portion extending in the first direction. A thickness in the first direction of the first conductive layer decreases the closer it comes to the contact electrode in a first range from the contact electrode to a position separated by a first distance in the second direction from the contact electrode. A thickness in the first direction of the connecting portion decreases the closer it comes to the extending portion in a second range from the first conductive layer to a certain position in the second direction between the first conductive layer and the extending portion.

### CROSS-REFERENCE TO RELATED APPLICATIONS

This application is based upon and claims the benefit of Japanese Patent Application No. 2025-039333, filed on Mar. 12, 2025, the entire contents of which are incorporated herein by reference.

### BACKGROUND

### Field

The present embodiments relate to semiconductor memory devices.

### Description of the Related Art

There is known a semiconductor memory device comprising: a plurality of memory cells arranged in a first direction; a plurality of conductive layers arranged in the first direction and connected to the plurality of memory cells; and a contact electrode extending in the first direction and connected to one of the plurality of conductive layers.

### BRIEF DESCRIPTION OF THE DRAWINGS

FIG. 1 is a schematic circuit diagram showing a part of a configuration of a semiconductor memory device according to a first embodiment;

FIG. 2 is a schematic plan view showing a configuration of the semiconductor memory device;

FIG. 3 is a schematic plan view showing a part of a configuration of a semiconductor column region R_{MH};

FIG. 4 is a schematic cross-sectional view showing a part of a configuration of the semiconductor column region R_{MH};

FIG. 5 is a schematic cross-sectional view showing a part of a configuration of the semiconductor column region R_{MH};

FIG. 6 is a schematic plan view showing a part of a configuration of a hook-up region R_{HU};

FIG. 7 is a schematic cross-sectional view showing a part of a configuration of the hook-up region R_{HU};

FIG. 8 is a schematic cross-sectional view showing a part of a configuration of the hook-up region R_{HU};

FIG. 9 is a schematic cross-sectional view for explaining a method of manufacturing the semiconductor memory device according to the first embodiment;

FIG. 10 is a schematic cross-sectional view for explaining the method of manufacturing;

FIG. 11 is a schematic cross-sectional view for explaining the method of manufacturing;

FIG. 12 is a schematic cross-sectional view for explaining the method of manufacturing;

FIG. 13 is a schematic cross-sectional view for explaining the method of manufacturing;

FIG. 14 is a schematic cross-sectional view for explaining the method of manufacturing;

FIG. 15 is a schematic cross-sectional view for explaining the method of manufacturing;

FIG. 16 is a schematic cross-sectional view for explaining the method of manufacturing;

FIG. 17 is a schematic cross-sectional view for explaining the method of manufacturing;

FIG. 18 is a schematic cross-sectional view for explaining the method of manufacturing;

FIG. 19 is a schematic cross-sectional view for explaining the method of manufacturing;

FIG. 20 is a schematic cross-sectional view for explaining the method of manufacturing;

FIG. 21 is a schematic cross-sectional view for explaining the method of manufacturing;

FIG. 22 is a schematic cross-sectional view for explaining the method of manufacturing;

FIG. 23 is a schematic cross-sectional view for explaining the method of manufacturing;

FIG. 24 is a schematic cross-sectional view for explaining the method of manufacturing;

FIG. 25 is a schematic cross-sectional view for explaining the method of manufacturing;

FIG. 26 is a schematic cross-sectional view for explaining the method of manufacturing;

FIG. 27 is a schematic cross-sectional view for explaining the method of manufacturing;

FIG. 28 is a schematic cross-sectional view for explaining the method of manufacturing;

FIG. 29 is a schematic cross-sectional view for explaining the method of manufacturing;

FIG. 30 is a schematic cross-sectional view for explaining the method of manufacturing;

FIG. 31 is a schematic cross-sectional view for explaining the method of manufacturing;

FIG. 32 is a schematic cross-sectional view for explaining the method of manufacturing;

FIG. 33 is a schematic cross-sectional view for explaining the method of manufacturing;

FIG. 34 is a schematic cross-sectional view showing a part of a configuration of a semiconductor memory device according to a comparative example;

FIG. 35 is a schematic cross-sectional view showing a part of a configuration of a semiconductor memory device according to a second embodiment;

FIG. 36 is a schematic cross-sectional view showing a part of a configuration of the semiconductor memory device according to the second embodiment;

FIG. 37 is a schematic cross-sectional view for explaining a first method of manufacturing the semiconductor memory device according to the second embodiment;

FIG. 38 is a schematic cross-sectional view for explaining the method of manufacturing;

FIG. 39 is a schematic cross-sectional view for explaining the method of manufacturing;

FIG. 40 is a schematic cross-sectional view for explaining the method of manufacturing;

FIG. 41 is a schematic cross-sectional view for explaining the method of manufacturing;

FIG. 42 is a schematic cross-sectional view for explaining a second method of manufacturing the semiconductor memory device according to the second embodiment;

FIG. 43 is a schematic cross-sectional view for explaining the method of manufacturing;

FIG. 44 is a schematic cross-sectional view for explaining the method of manufacturing;

FIG. 45 is a schematic cross-sectional view for explaining a method of manufacturing a semiconductor memory device according to a third embodiment;

FIG. 46 is a schematic cross-sectional view showing a part of a configuration of the semiconductor memory device according to the third embodiment;

FIG. 47 is a schematic cross-sectional view showing a part of a configuration of the semiconductor memory device according to the third embodiment;

FIG. 48 is a schematic cross-sectional view for explaining a method of manufacturing a semiconductor memory device according to another embodiment;

FIG. 49 is a schematic cross-sectional view showing a part of a configuration of the semiconductor memory device according to another embodiment;

FIG. 50 is a schematic cross-sectional view showing a part of a configuration of the semiconductor memory device according to another embodiment;

FIG. 51 is a schematic cross-sectional view showing a part of a configuration of a semiconductor memory device according to still another embodiment.

### DETAILED DESCRIPTION

A semiconductor memory device according to one embodiment comprises: a plurality of memory cells arranged in a first direction; a plurality of conductive layers arranged in the first direction and connected to the plurality of memory cells; and a contact electrode. The contact electrode includes: a connecting portion connected to a first conductive layer among the plurality of conductive layers at a position in the first direction corresponding to the first conductive layer; and an extending portion extending in the first direction from one side to the other side in the first direction with respect to the first conductive layer. A thickness in the first direction of the first conductive layer decreases the closer the first conductive layer comes to the contact electrode within a first range from a contact surface with the contact electrode in a second direction intersecting the first direction of the first conductive layer to a position separated by a first distance in the second direction from the contact electrode of the first conductive layer. A thickness in the first direction of the connecting portion of the contact electrode decreases the closer the connecting portion comes to the extending portion within a second range from a contact surface with the first conductive layer in the second direction of the connecting portion to a certain position in the second direction between the contact surface and the extending portion of the connecting portion.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, a part of a configuration, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been connected in series, the first transistor is still “electrically connected” to the third transistor even when the second transistor is in an OFF state.

Moreover, in the present specification, when a circuit, or the like, is said to “make electrically conductive” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction intersecting a certain plane will sometimes be referred to as a first direction. Moreover, a direction along the plane will sometimes be referred to as a second direction, and a direction intersecting the second direction along the plane will sometimes be referred to as a third direction. The first direction, the second direction, and the third direction may coincide with any of the Z-direction, the X-direction, and the Y-direction, but need not do so.

Moreover, in the present specification, expressions such as “above” or “below” will be defined with reference to a substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting the X-direction or the Y-direction will be referred to as a side surface, and so on.

Moreover, in the present specification, when the likes of a “width”, a “length”, or a “thickness” in a certain direction is referred to for a configuration, a member, and so on, this will sometimes mean a width, a length, or a thickness, and so on, in a cross section observed by the likes of SEM (Scanning Electron Microscopy) or TEM (Transmission Electron Microscopy), and so on.

### First Embodiment

### [Circuit Configuration]

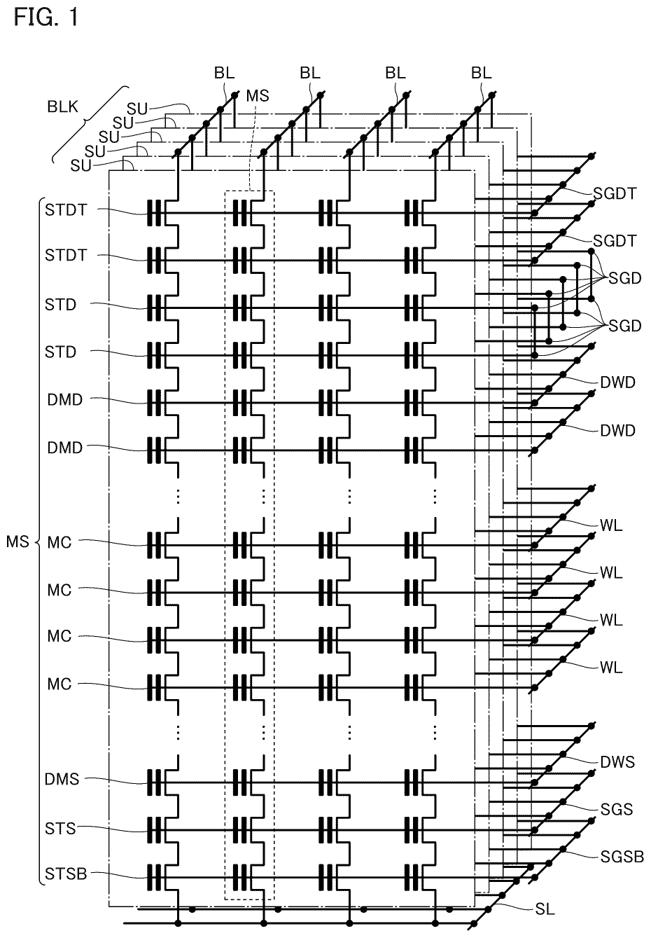

FIG. 1 is a schematic circuit diagram showing a part of a configuration of a semiconductor memory device according to a first embodiment. The semiconductor memory device according to the present embodiment comprises a memory block BLK. The memory block BLK comprises a plurality of string units SU. These plurality of string units SU each comprise a plurality of memory strings MS. One ends of these plurality of memory strings MS are each connected to a peripheral circuit via bit lines BL. Moreover, the other ends of these plurality of memory strings MS are each connected to the peripheral circuit via a common source line SL.

The memory string MS comprises: drain side select transistors STDT, STD; one or a plurality of dummy memory cells DMD; a plurality of memory cells MC (memory transistors); one or a plurality of dummy memory cells DMS; and source side select transistors STS, STSB. The drain side select transistors STDT, STD, the one or plurality of dummy memory cells DMD, the plurality of memory cells MC, the one or plurality of dummy memory cells DMS, and the source side select transistors STS, STSB are connected in series between the bit line BL and the source line SL. Hereafter, the drain side select transistors STDT, STD and the source side select transistor STS, STSB will sometimes simply be referred to as select transistors STDT, STD, STS, STSB.

The memory cell MC is a field effect type transistor. The memory cell MC comprises a part of a semiconductor column, a gate insulating film, and a gate electrode. The part of the semiconductor column functions as a channel region. The gate insulating film includes an electric charge accumulating film. A threshold voltage of the memory cell MC changes according to an amount of charge in the electric charge accumulating film. The memory cell MC stores 1 bit or a plurality of bits of data. Note that the gate electrodes of the plurality of memory cells MC corresponding to one memory string MS are each connected with word lines WL. These word lines WL are each commonly connected to all of the memory strings MS in one memory block BLK.

The dummy memory cells DMD, DMS are basically configured similarly to the memory cell MC. However, the dummy memory cells DMD, DMS do not have data stored therein. Note that the gate electrodes of the one or plurality of dummy memory cells DMD corresponding to one memory string MS are each connected with dummy word lines DWD. These dummy word lines DWD are each commonly connected to all of the memory strings MS in one memory block BLK. Similarly, the gate electrodes of the one or plurality of dummy memory cells DMS corresponding to one memory string MS are each connected with dummy word lines DWS. These dummy word lines DWS are each commonly connected to all of the memory strings MS in one memory block BLK.

The select transistors STDT, STD, STS, STSB are each a field effect type transistor. The select transistors STDT, STD, STS, STSB each comprise a part of a semiconductor column, a gate insulating film, and a gate electrode. The part of the semiconductor column functions as a channel region. The gate electrodes of the select transistors STDT, STD, STS, STSB are respectively connected with select gate lines SGDT, SGD, SGS, SGSB. The drain side select gate line SGDT is commonly connected to all of the memory strings MS in one memory block BLK. The drain side select gate line SGD is commonly connected to all of the memory strings MS in one string unit SU. The source side select gate line SGS is commonly connected to all of the memory strings MS in one memory block BLK. The source side select gate line SGSB is commonly connected to all of the memory strings MS in one memory block BLK.

### [Structure]

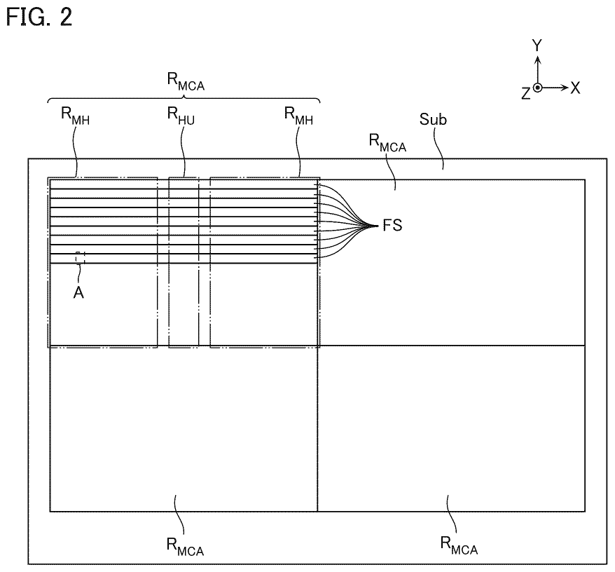

FIG. 2 is a schematic plan view showing a configuration of the semiconductor memory device according to the present embodiment. The semiconductor memory device according to the present embodiment comprises a semiconductor substrate Sub. In the example illustrated, the semiconductor substrate Sub is provided with four memory cell array regions Ruca arranged in the X-direction and the Y-direction.

The memory cell array region R_{MCA} comprises a plurality of finger structures FS arranged in the Y-direction. In the present embodiment, one finger structure FS functions as one memory block BLK (FIG. 1). However, a plurality of the finger structures FS may function as one memory block BLK.

Moreover, the memory cell array regions R_{MCA} each comprise: two semiconductor column regions R_{MH} arranged in the X-direction; and a hook-up region R_{HU} provided between these two semiconductor column regions R_{MH}. Structure in these regions will be described in order below.

### [Structure in Semiconductor Column Region R_{MH}]

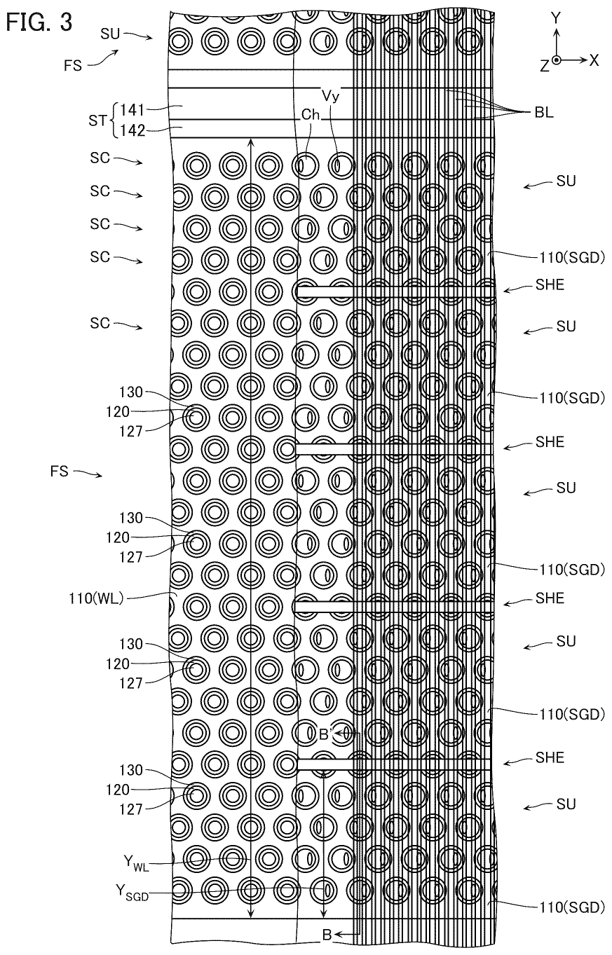

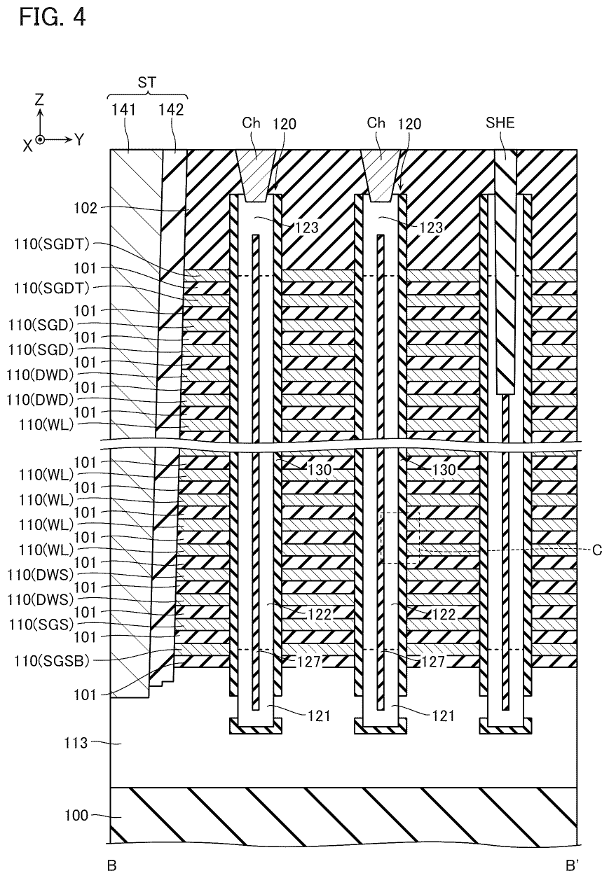

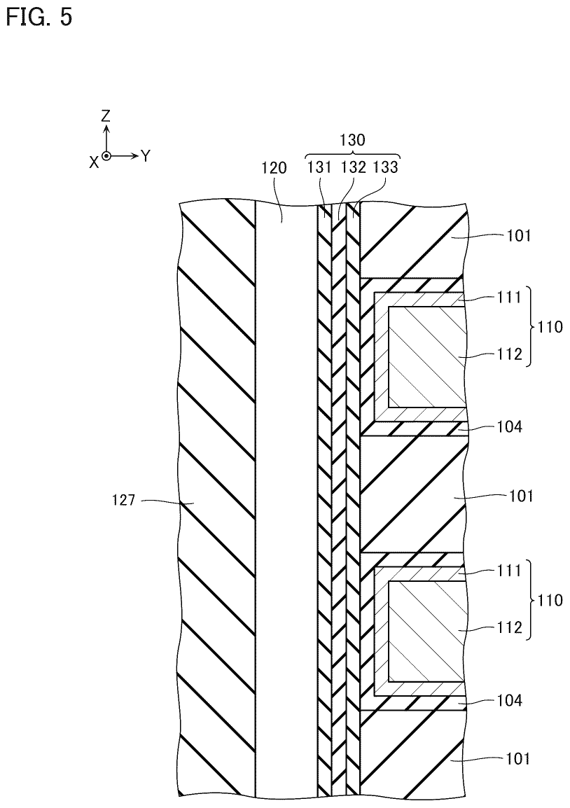

First, a structure in the semiconductor column region R_{MH} will be described with reference to FIGS. 3 to 5. FIG. 3 is a schematic plan view showing a part of a configuration of the semiconductor column region R_{MH}, and it enlarges and shows the portion indicated by A in FIG. 2. A certain region of FIG. 3 shows an XY cross section at a height position corresponding to a later-mentioned conductive layer 110(WL). The remaining region of FIG. 3 shows a view of the portion indicated by A in FIG. 2 viewed from above. Moreover, in this remaining region, later-mentioned insulating layers 101, 102 and a later-mentioned conductive layer 110(SGDT) are omitted. Moreover, in a part of this remaining region, the bit lines BL are omitted. FIG. 4 is a schematic cross-sectional view showing a part of a configuration of the semiconductor column region R_{MH}, and it shows a cross section of the structure shown in FIG. 3 taken along the line B-B′ and viewed along a direction of the arrows. FIG. 5 is a schematic cross-sectional view showing a part of a configuration of the semiconductor column region R_{MH}, and it enlarges and shows the portion indicated by C in FIG. 4. Note that although FIG. 5 shows a YZ cross section, a similar structure to in FIG. 5 will be observed, even when a cross section other than a YZ cross section along a central axis of a later-mentioned semiconductor column 120 (for example, an XZ cross section) is observed.

As shown in FIG. 3, for example, the finger structure FS comprises five of the string units SU arranged in the Y-direction. An inter-finger structure ST is provided between two finger structures FS adjacent in the Y-direction. Moreover, an inter-string unit insulating member SHE is provided between two string units SU adjacent in the Y-direction. Note that the finger structure FS may comprise two to four string units SU, or may comprise six or more string units SU.

As shown in FIG. 4, the finger structure FS comprises a plurality of conductive layers 110 arranged in the Z-direction. A conductive layer 113 is provided below the plurality of conductive layers 110. In addition, the finger structure FS comprises a plurality of semiconductor columns 120 extending in the Z-direction penetrating the plurality of conductive layers 110. Moreover, respective gate insulating films 130 are provided between the plurality of conductive layers 110 and the plurality of semiconductor columns 120.

The conductive layer 110 comprises a substantially plate-like shape extending in the X-direction. The conductive layer 110 may include the likes of a stacked film having stacked therein a barrier conductive film 111 of the likes of titanium nitride (TiN) and a metal film 112 of the likes of tungsten (W), as shown in FIG. 5, for example, or may include the likes of polycrystalline silicon including an impurity such as phosphorus (P) or boron (B). Moreover, upper and lower surfaces, and a surface facing the semiconductor column 120, of the conductive layer 110 may be provided with a high-dielectric-constant insulating film 104. The high-dielectric-constant insulating film 104 may include a metal oxide film of the likes of aluminum oxide (AlO), hafnium oxide (HfO), or zirconium oxide (ZrO), for example.

As shown in FIG. 4, the finger structure FS comprises: the plurality of conductive layers 110 and a plurality of insulating layers 101 arranged alternately in the Z-direction; and an insulating layer 102 provided above these pluralities of conductive layers 110 and insulating layers 101. The insulating layers 101, 102 include the likes of silicon oxide (SiO₂). For example, a thickness in the Z-direction of the insulating layer 102 is greater than a thickness in the Z-direction of the insulating layer 101.

A part of the plurality of conductive layers 110 function as the word lines WL (FIG. 1) and as the gate electrodes of the plurality of memory cells MC (FIG. 1) connected to these word lines WL. In the following description, as shown in FIG. 4, for example, such a conductive layer 110 will sometimes be referred to as a conductive layer 110(WL). The plurality of conductive layers 110(WL) are each electrically independent every finger structure FS. Side surfaces on a positive side in the Y-direction and a negative side in the Y-direction of the conductive layer 110(WL) are electrically insulated from configurations in another finger structure FS, via the inter-finger structure ST.

One or a plurality of conductive layers 110 disposed below the plurality of conductive layers 110(WL) function as the dummy word line DWS (FIG. 1) and as the gate electrodes of the plurality of dummy memory cells DMS (FIG. 1) connected to this dummy word line DWS. In the following description, such a conductive layer 110 will sometimes be referred to as a conductive layer 110(DWS). The conductive layer 110(DWS) is configured similarly to the conductive layer 110(WL).

One or a plurality of conductive layers 110 disposed below the one or plurality of conductive layers 110(DWS) function as the source side select gate line SGS (FIG. 1) and as the gate electrodes of the plurality of source side select transistors STS (FIG. 1) connected to this source side select gate line SGS. In the following description, such a conductive layer 110 will sometimes be referred to as a conductive layer 110(SGS). The conductive layer 110(SGS) is configured similarly to the conductive layer 110(WL).

One or a plurality of conductive layers 110 disposed below the one or plurality of conductive layers 110(SGS) function as the source side select gate line SGSB (FIG. 1) and as the gate electrodes of the plurality of source side select transistors STSB (FIG. 1) connected to this source side select gate line SGSB. In the following description, such a conductive layer 110 will sometimes be referred to as a conductive layer 110(SGSB). The conductive layer 110(SGSB) is configured similarly to the conductive layer 110(WL).

One or a plurality of conductive layers 110 disposed above the plurality of conductive layers 110(WL) function as the dummy word line DWD (FIG. 1) and as the gate electrodes of the plurality of dummy memory cells DMD (FIG. 1) connected to this dummy word line DWD. In the following description, such a conductive layer 110 will sometimes be referred to as a conductive layer 110(DWD). A part of the conductive layers 110(DWD) may be configured similarly to the conductive layer 110(WL). Others of the conductive layers 110(DWD) provided above these parts of the conductive layers 110(DWD) may be basically configured similarly to a later-mentioned conductive layer 110(SGD). However, the five conductive layers 110(DWD) arranged in the Y-direction at a certain height position in one finger structure FS are electrically conductive with each other.

One or a plurality of conductive layers 110 disposed above the one or plurality of conductive layers 110(DWD) function as the drain side select gate line SGD (FIG. 1) and as the gate electrodes of the plurality of drain side select transistors STD (FIG. 1) connected to this drain side select gate line SGD. In the following description, such a conductive layer 110 will sometimes be referred to as a conductive layer 110(SGD).

As shown in FIG. 3, the finger structure FS includes five conductive layers 110(SGD) arranged in the Y-direction, via the inter-string unit insulating members SHE, at a certain height position. A width Y_{SGD} in the Y-direction of the conductive layer 110(SGD) is less than a width Y_{WL} in the Y-direction of the conductive layer 110(WL). These five conductive layers 110(SGD) are each electrically independent every string unit SU. In each finger structure FS, the conductive layers 110(SGD) corresponding to the 1^{st} and 5^{th} string units SU counting from one side in the Y-direction (for example, a negative side in the Y-direction) are electrically insulated from configurations in another finger structure FS, via the inter-finger structure ST provided between the finger structures FS. Moreover, in each finger structure FS, two conductive layers 110(SGD) adjacent in the Y-direction are electrically insulated via the inter-string unit insulating member SHE.

One or a plurality of conductive layers 110 disposed above the conductive layer 110(SGD) function as the drain side select gate line SGDT (FIG. 1) and as the gate electrodes of the plurality of drain side select transistors STDT (FIG. 1) connected to this drain side select gate line SGDT. In the following description, such a conductive layer 110 will sometimes be referred to as a conductive layer 110(SGDT). The conductive layer 110(SGDT) is basically configured similarly to the conductive layer 110(SGD). However, the five conductive layers 110(SGDT) arranged in the Y-direction at a certain height position in one finger structure FS are electrically conductive with each other.

The conductive layer 113 (FIG. 4) may include the likes of polycrystalline silicon including an impurity such as phosphorus (P) or boron (B), for example. Moreover, a lower surface of the conductive layer 113 may be provided with a metal such as tungsten (W), a conductive layer of the likes of tungsten silicide, or another conductive layer, for example. The insulating layer 101 of the likes of silicon oxide (SiO₂) is provided between the conductive layer 113 and the conductive layer 110. Moreover, an insulating layer 100 of the likes of silicon oxide (SiO₂) is provided below the conductive layer 113.

The conductive layer 113 functions as a part of the source line SL (FIG. 1). The conductive layer 113 is commonly provided for all of the finger structures FS included in the memory cell array region R_{MCA} (FIG. 2), for example.

As shown in FIG. 3, for example, the semiconductor columns 120 are arranged in a certain pattern in the X-direction and the Y-direction. For example, the finger structure FS comprises 24 semiconductor column rows SC provided from one side in the Y-direction to the other side in the Y-direction. These 24 semiconductor column rows SC each comprise a plurality of the semiconductor columns 120 arranged in the X-direction. Those semiconductor column rows SC provided at 5n+1^{th} through 5n+4^{th} positions (where n is an integer from 0 to 4) counting from one side in the Y-direction, of these 24 semiconductor column rows SC are included in the string unit SU. Moreover, those semiconductor column rows SC provided at 5^{th}, 10^{th}, 15^{th}, and 20^{th} positions counting from one side in the Y-direction, of these 24 semiconductor column rows SC are provided at positions overlapping the inter-string unit insulating members SHE, viewed in the Z-direction, and do not function as a device.

The semiconductor column 120 includes the likes of polycrystalline silicon (Si), for example. As shown in FIG. 4, for example, the semiconductor column 120 has a substantially cylindrical shape, and, in its central portion, is provided with an insulating column 127 of the likes of silicon oxide (SiO₂).

The semiconductor column 120 comprises: a region 121 provided at a lower end portion of the semiconductor column 120; a region 122 provided above the region 121, but provided below an upper surface of the uppermost conductive layer 110; and a region 123 provided above the region 122.

The region 121 includes an N-type impurity such as phosphorus (P). The region 121 comprises a substantially cylindrical shape. The region 121 is connected to the conductive layer 113. The region 122 faces the plurality of conductive layers 110.

The region 122 functions as channel regions of the memory cells MC (FIG. 1), the dummy memory cells DMD, DMS (FIG. 1), and the select transistors STDT, STD, STS, STSB (FIG. 1). The region 122 need not include an N-type impurity such as phosphorus (P).

The region 123 includes an N-type impurity such as phosphorus (P). The region 123 is electrically connected to the bit line BL extending in the Y-direction (FIG. 3), via a contact electrode Ch and a contact electrode Vy extending in the Z-direction (FIG. 3). The contact electrode Ch and the contact electrode Vy may include the likes of a stacked film having stacked therein a barrier conductive film of the likes of titanium nitride (TiN) and a metal film of the likes of tungsten (W), for example. The bit line BL may include the likes of a stacked film having stacked therein a barrier conductive film of the likes of titanium nitride (TiN) and a metal film of the likes of copper (Cu), for example.

As shown in FIG. 5, for example, the gate insulating film 130 comprises a tunnel insulating film 131, an electric charge accumulating film 132, and a block insulating film 133 that are stacked between the semiconductor column 120 and the conductive layer 110. The tunnel insulating film 131 and the block insulating film 133 include the likes of silicon oxide (SiO₂), for example. The electric charge accumulating film 132 is a film capable of accumulating a charge, of the likes of silicon nitride (SiN), for example. The gate insulating film 130 has a substantially cylindrical shape, and extends in the Z-direction along an outer peripheral surface of the semiconductor column 120 excluding a contact portion of the semiconductor column 120 and the conductive layer 113.

As shown in FIGS. 3 and 4, for example, the inter-finger structure ST comprises: an inter-finger electrode 141 extending in the X-direction and the Z-direction; and inter-finger insulating members 142 of the likes of silicon oxide (SiO₂), provided on side surfaces in the Y-direction of the inter-finger electrode 141. A lower end of the inter-finger electrode 141 is connected to the conductive layer 113. Moreover, an upper end of the inter-finger electrode 141 is located above the upper surface of the uppermost conductive layer 110. The inter-finger electrode 141 may include the likes of a stacked film having stacked therein a barrier conductive film of the likes of titanium nitride (TiN) and a metal film of the likes of tungsten (W), for example. Moreover, the inter-finger electrode 141 may include the likes of polycrystalline silicon including an impurity such as phosphorus (P) or boron (B), for example. The inter-finger electrode 141 functions as a part of the source line SL (FIG. 1), for example.

The inter-string unit insulating member SHE includes the likes of silicon oxide (SiO₂), for example. As shown in FIG. 3, for example, the inter-string unit insulating member SHE is provided between two string units SU arranged in the Y-direction in the finger structure FS, and extends in the X-direction. As shown in FIG. 4, the inter-string unit insulating member SHE extends in the Z-direction within a height range corresponding to the insulating layer 102, the conductive layers 110(SGDT), 110(SGD), and a part of conductive layers 110(DWD), and to the insulating layers 101 provided on upper and lower surfaces of these conductive layers 110, and divides these configurations in the Y-direction.

### [Structure in Hook-Up Region R_{HU}]

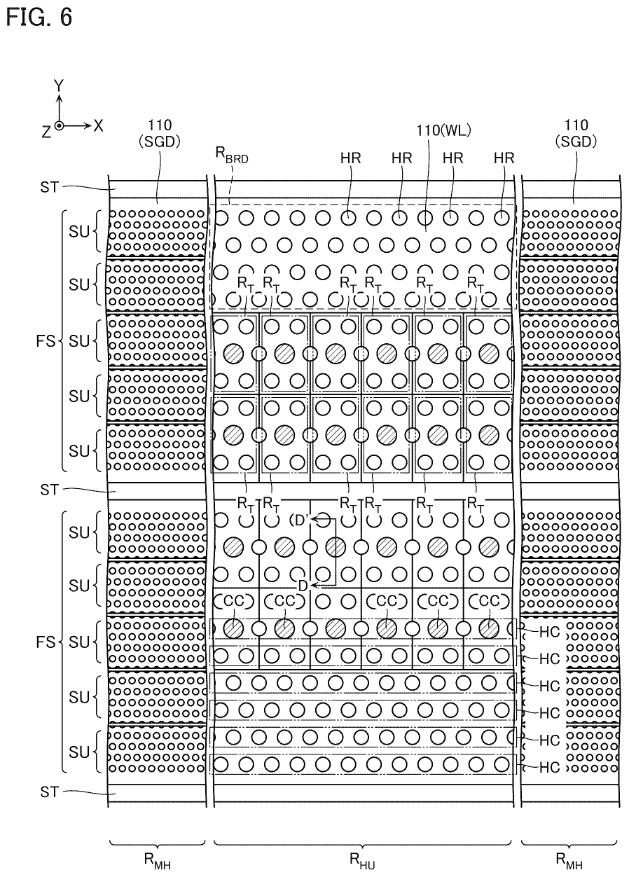

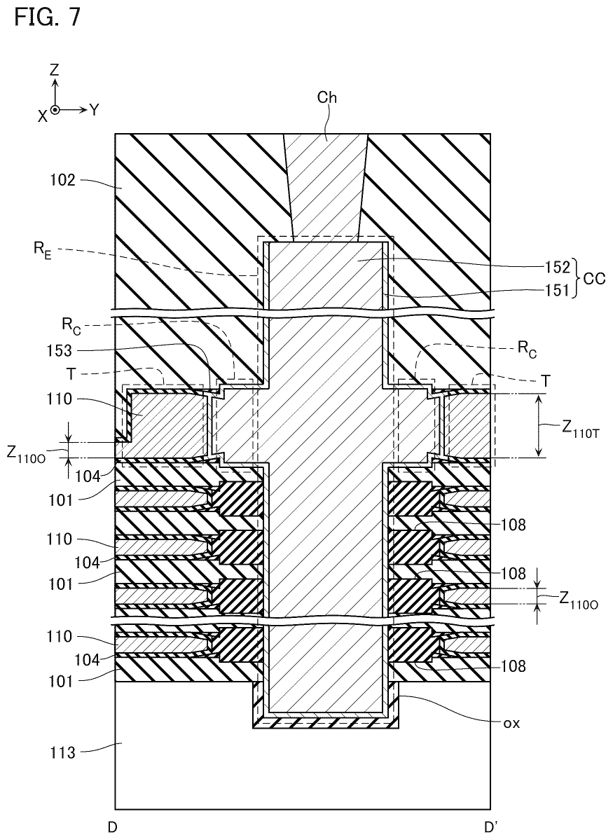

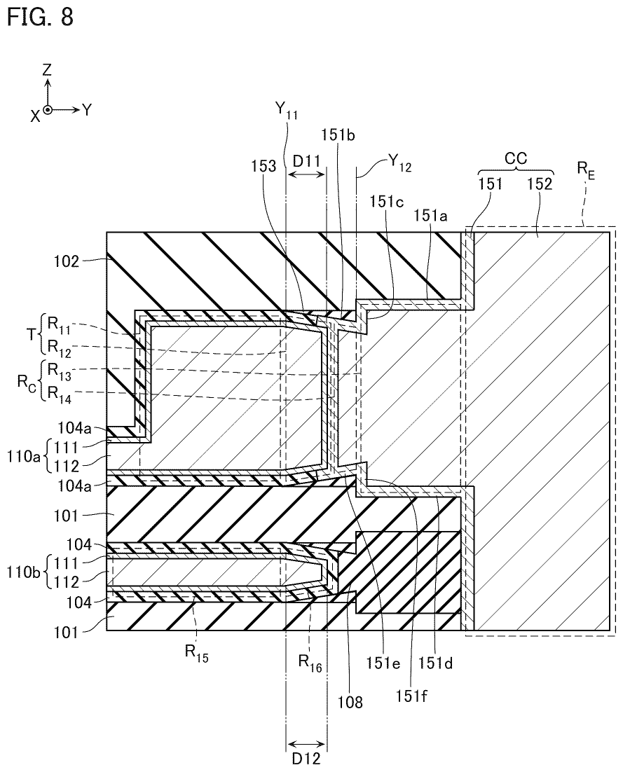

Next, a structure in the hook-up region R_{HU} will be described with reference to FIGS. 6 to 8. FIG. 6 is a schematic plan view showing a part of a configuration of the hook-up region R_{HU}. In FIG. 6, the insulating layers 101, 102, the conductive layer 110(SGDT), the bit line BL, and so on, are omitted. FIG. 7 is a schematic cross-sectional view showing a part of a configuration of the hook-up region R_{HU}, and it shows a cross section of the structure shown in FIG. 6 taken along the line D-D′ and viewed along a direction of the arrows. FIG. 8 is a schematic cross-sectional view showing a part of a configuration of the hook-up region R_{HU}, and it enlarges and shows a part of FIG. 7. Note that although FIG. 8 shows a YZ cross section, a similar structure to in FIG. 8 will be observed, even when a cross section other than a YZ cross section along a central axis of a later-mentioned contact electrode CC (for example, an XZ cross section) is observed.

The hook-up region R_{HU} exemplified in FIG. 6 comprises a bridge region R_{BRD} and a plurality of terrace regions RT.

The bridge region R_{BRD} is provided with the conductive layers 110(WL), 110(DWD), 110(DWS), 110(SGS), 110(SGSB). The conductive layers 110(WL), 110(DWD), 110(DWS), 110(SGS), 110(SGSB) extend in the X-direction from an end portion on one side in the X-direction of the hook-up region Reu to an end portion on the other side in the X-direction of the hook-up region R_{HU}, in the bridge region R_{BRD}.

The plurality of terrace regions Rr are provided correspondingly to the plurality of conductive layers 110 arranged in the Z-direction and are provided on one side in the Y-direction with respect to the bridge region R_{BRD}. These plurality of terrace regions Rr each comprise a terrace portion T of a corresponding conductive layer 110. The terrace portion T is a portion that, viewed from above, does not overlap another conductive layer 110, for example. As shown in FIG. 7, the terrace portion T is covered by the insulating layer 102. Note that in the present embodiment, a thickness Z_{110T} in the Z-direction of the terrace portion T of the conductive layer 110 is greater than a thickness Z_{110O} in the Z-direction of a portion different from the terrace portion T of the conductive layer 110.

Moreover, the hook-up region R_{HU} is provided with a plurality of support insulating columns HR (FIG. 6). The support insulating column HR may include silicon oxide (SiO₂), or may comprise a configuration corresponding to the semiconductor column 120, insulating column 127, and gate insulating film 130, for example. The support insulating column HR extends in the Z-direction penetrating the plurality of conductive layers 110. An outer peripheral surface of the support insulating column HR is surrounded by through-holes each provided in the insulating layer 102 and in the plurality of conductive layers 110 and the plurality of insulating layers 101.

As shown in FIG. 6, for example, the support insulating columns HR are arranged in a certain pattern in the X-direction and the Y-direction. For example, the finger structure FS comprises 10 support insulating column rows HC provided from one side in the Y-direction to the other side in the Y-direction. These 10 support insulating column rows HC each comprise a plurality of the support insulating columns HR arranged in the X-direction. Note that in the example illustrated, in a part of the support insulating column rows HC provided at positions corresponding to the terrace regions Rr, a part of the support insulating columns HR are omitted, and contact electrodes CC are provided instead.

The contact electrodes CC are each provided correspondingly to the plurality of terrace portions T. As shown in FIG. 7, the contact electrode CC extends in the Z-direction penetrating the plurality of conductive layers 110. An upper end portion of the contact electrode CC is connected to the contact electrode Ch.

The contact electrode CC comprises: a connecting portion R_{C} which is provided at a height position corresponding to the terrace portion T of a corresponding conductive layer 110, and contacts the terrace portion T of this conductive layer 110; and an extending portion R_{E} extending in the Z-direction.

An outer peripheral surface of the connecting portion R_{C} contacts the conductive layer 110. Radius in an XY cross section of the connecting portion R_{C} is greater than radius in an XY cross section of the extending portion R_{E}.

An outer peripheral surface of a portion provided above the connecting portion R_{C}, of the extending portion R_{E} is surrounded by a through-hole provided in the insulating layer 102. An outer peripheral surface of a portion provided below the connecting portion R_{C}, of the extending portion R_{E} is surrounded by a through-hole provided in the plurality of conductive layers 110 and the plurality of insulating layers 101. Moreover, a plurality of insulating layers 108 are provided between the extending portion R_{E} and a plurality of conductive layers 110 disposed below the connecting portion R_{C}. The contact electrode CC is insulated from the plurality of conductive layers 110 disposed below the connecting portion R_{C} via the plurality of the insulating layers 108. The insulating layer 108 may include the likes of silicon oxide (SiO₂). Moreover, in the example illustrated, a lower end portion of the extending portion R_{E} is provided below an upper surface of the conductive layer 113, and is covered by an oxide portion ox. The contact electrode CC is insulated from the conductive layer 113 via this oxide portion ox. The oxide portion ox may include the likes of silicon oxide (SiO₂).

The contact electrode CC comprises a barrier conductive film 151 and a metal film 152, for example. The barrier conductive film 151 covers outer peripheral surfaces of portions of the metal film 152 provided in the connecting portion R_{C} and the extending portion R_{E}, and upper and lower surfaces of the portion of the metal film 152 provided in the connecting portion R_{C}. The barrier conductive film 151 may include the likes of titanium nitride (TiN) or tantalum nitride (TaN), for example. The metal film 152 may include the likes of tungsten (W), molybdenum (Mo), or ruthenium (Ru), for example. The barrier conductive film 151 and the metal film 152 extend in the Z-direction from a lower end to an upper end of the contact electrode CC.

Next, shapes of the terrace portion T of the conductive layer 110 and the connecting portion R_{C} of the contact electrode CC will be described with reference to FIG. 8. In FIG. 8, the conductive layer 110 connected to the contact electrode CC is shown as a conductive layer 110a. Moreover, the conductive layer 110 provided below the conductive layer 110a and adjacent to the conductive layer 110a is shown as a conductive layer 110b.

In the present embodiment, a thickness in the Z-direction of the terrace portion T of the conductive layer 110a is substantially fixed in a range R₁₁ on an opposite side to the contact electrode CC with respect to a position Yu separated by a distance D11 from the contact electrode CC. Moreover, the thickness in the Z-direction of the terrace portion T of the conductive layer 110a decreases the closer the terrace portion T comes to the contact electrode CC in a range R₁₂ from a contact surface with the contact electrode CC of the conductive layer 110a to the position Y₁₁. A thickness in the Z-direction at an end portion on a range R₁₁ side of the range R₁₂ of the terrace portion T matches a thickness in the range R₁₁ of the terrace portion T.

Moreover, in the present embodiment, a thickness in the Z-direction of the connecting portion R_{C} is substantially fixed in a range R₁₃ from a position Y₁₂ in the X-direction between a contact surface with the conductive layer 110a of the connecting portion R_{C} and the extending portion R_{E}, to the extending portion R_{E}. Moreover, a thickness in the Z-direction of the connecting portion R_{C} decreases the closer the connecting portion R_{C} comes to the extending portion R_{E} in a range R₁₄ from a contact surface with the conductive layer 110a of the connecting portion R_{C} to the position Y₁₂. A thickness in the Z-direction at an end portion on a range R₁₃ side of the range R₁₄ of the connecting portion R_{C} is smaller than a thickness in the range R₁₃ of the connecting portion R_{C}. At the position Y₁₂, an upper surface and a lower surface of the connecting portion R_{C} each have a step formed therein.

The barrier conductive film 151 comprises: a film portion 151a covering an upper surface of the metal film 152 in the range R₁₃; a film portion 151b covering the upper surface of the metal film 152 in the range R₁₄; and a stepped film portion 151c connected to these film portions 151a, 151b between the film portions 151a, 151b. In addition, the barrier conductive film 151 comprises: a film portion 151d covering a lower surface of the metal film 152 in the range R₁₃; a film portion 151e covering the lower surface of the metal film 152 in the range R₁₄; and a stepped film portion 151f connected to these film portions 151d, 151e between the film portions 151d, 151e.

Moreover, as mentioned above, the upper and lower surfaces of each of the conductive layers 110 are each provided with the high-dielectric-constant insulating films 104. Hereafter, high-dielectric-constant insulating films 104 provided on upper and lower surfaces of the conductive layer 110a, of the plurality of high-dielectric-constant insulating films 104 will be referred to as high-dielectric-constant insulating films 104a. An end portion on a contact electrode CC side of the high-dielectric-constant insulating film 104a is provided in the above-described range R₁₂. Moreover, a thickness in the Z-direction of a structure consisting of the conductive layer 110a, the connecting portion R_{C}, and the high-dielectric-constant insulating films 104a decreases the closer the structure comes to the extending portion R_{E} over the above-described ranges R₁₂, R₁₄.

Moreover, as shown in FIG. 8, in the ranges R₁₂, R₁₄, upper and lower surfaces of the high-dielectric-constant insulating films 104a and the connecting portion R_{C} are each provided with an oxide portion 153. A thickness in the Z-direction of a structure consisting of the conductive layer 110a, the connecting portion R_{C}, the high-dielectric-constant insulating films 104a, and the oxide portions 153 is substantially fixed over the above-described ranges R₁₁, R₁₂, R₁₄. Note that a thickness in the Z-direction in the above-described range R₁₃ of the connecting portion R_{C} is greater than a thickness in the Z-direction of this structure.

In the present embodiment, a thickness in the Z-direction of the conductive layer 110b is substantially fixed in a range R₁₅ on an opposite side to the contact electrode CC with respect to a position separated by a distance D12 from an end portion on a contact electrode CC side of the conductive layer 110b. Moreover, a thickness in the Z-direction of the conductive layer 110b decreases the closer the conductive layer 110b comes to the contact electrode CC in a range R₁₆ from the position separated by the distance D12 from the end portion on a contact electrode CC side of the conductive layer 110b, to the end portion on a contact electrode CC side of the conductive layer 110b. A thickness in the Z-direction at an end portion on a range R₁₅ side of the range R₁₆, of the conductive layer 110b matches a thickness in the range R₁₅ of the conductive layer 110b.

Note that in the example of FIG. 8, the above-described range R₁₂ and the above-described range R₁₆ substantially match, viewed in the Z-direction. Hence, the end portion on a contact electrode CC side of the high-dielectric-constant insulating film 104a is provided in the range R₁₆, viewed in the Z-direction.

Moreover, in the present embodiment, the steps formed on the upper surface and the lower surface of the connecting portion R_{C} at position Y₁₂ are provided at a contact electrode CC side with respect to an end portion on a contact electrode CC side of the conductive layer 110b.

### [Method of Manufacturing]

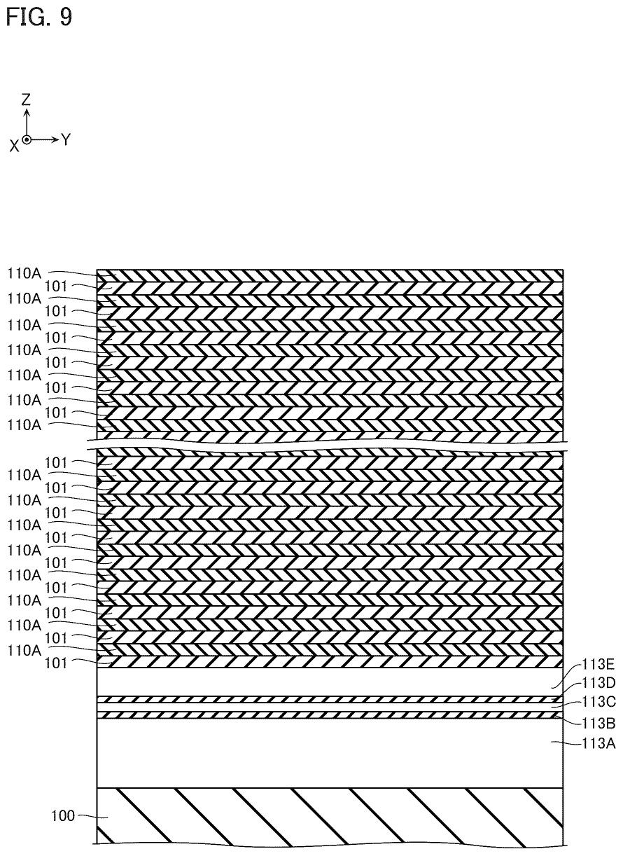

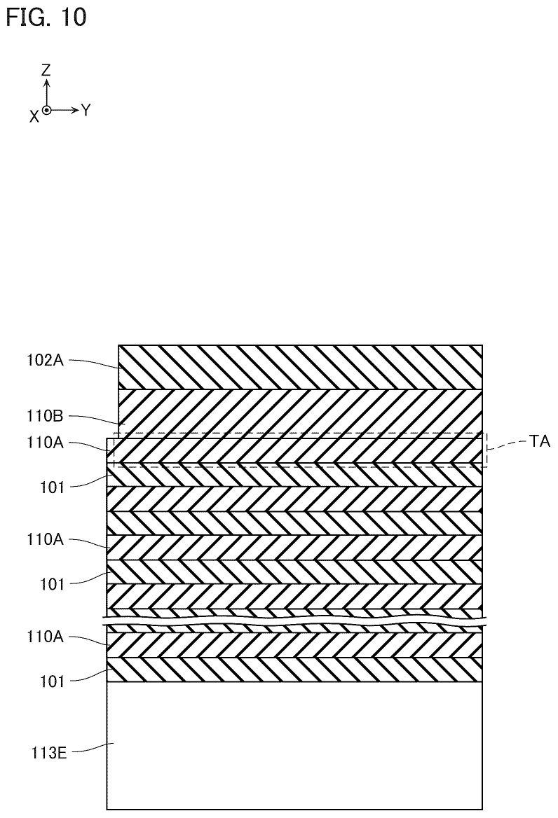

Next, a method of manufacturing the semiconductor memory device according to the first embodiment will be described with reference to FIGS. 9 to 33. FIGS. 9 to 33 are schematic cross-sectional views for explaining the method of manufacturing. FIGS. 9, 12 to 14, and 23 to 31 show cross sections corresponding to FIG. 4. FIGS. 10, 11, 15 to 22, 32, and 33 show cross sections corresponding to FIG. 7.

When manufacturing the semiconductor memory device according to the present embodiment, as shown in FIG. 9, for example, the insulating layer 100 is formed above an unillustrated semiconductor substrate. Next, a semiconductor layer 113A of the likes of silicon, a sacrifice layer 113B of the likes of silicon oxide, a sacrifice layer 113C of the likes of silicon, a sacrifice layer 113D of the likes of silicon oxide, and a semiconductor layer 113E of the likes of silicon, are formed on the insulating layer 100. In addition, the plurality of insulating layers 101 and a plurality of sacrifice layers 110A are alternately formed. The sacrifice layer 110A includes the likes of silicon nitride (SiN), for example. This step is performed by a method such as CVD (Chemical Vapor Deposition), for example.

Next, though illustration of the following is omitted, parts of the plurality of insulating layers 101 and the plurality of sacrifice layers 110A are removed, and a plurality of terrace portions TA (refer to FIG. 10) are formed, in the plurality of terrace regions Rr in the hook-up region R_{HU}. The terrace portion TA is a portion of the sacrifice layer 110A that, viewed from above, does not overlap another sacrifice layer 110A, for example. In this step, for example, a resist is formed on an upper surface of the sacrifice layer 110A. Moreover, removal of the sacrifice layer 110A, removal of the insulating layer 101, and removal of a part of the resist are repeatedly performed. Removal of the resist is performed by isotropic etching, such as wet etching. As a result, parts of the upper surfaces of the plurality of sacrifice layers 110A stacked in the Z-direction are exposed, and these exposed parts of the upper surfaces of the plurality of sacrifice layers 110A thereby become the terrace portions TA.

Next, as shown in FIG. 10, for example, a sacrifice layer 110B is formed on an upper surface of the terrace portion TA. In this step, for example, the sacrifice layer 110B including a similar material to the sacrifice layer 110A, and an insulating layer 102A of the likes of silicon oxide (SiO₂) are formed on the plurality of terrace portions TA and on side surfaces of the plurality of insulating layers 101 and the plurality of sacrifice layers 110A exposed due to formation of the terrace portions TA. A film thickness of portions covering the terrace portion TA, of these sacrifice layer 110B and insulating layer 102A is greater than a film thickness of portions covering the side surfaces of the plurality of insulating layers 101 and the plurality of sacrifice layers 110A, of these sacrifice layer 110B and insulating layer 102A. This step is performed by the likes of CVD, for example. Next, the portion formed on the side surfaces of the plurality of insulating layers 101 and the plurality of sacrifice layers 110A, of the insulating layer 102A is removed, leaving the portion covering the terrace portion TA, of the insulating layer 102A. This step is performed by isotropic etching, such as wet etching. Next, the portion formed on the side surfaces of the plurality of insulating layers 101 and the plurality of sacrifice layers 110A, of the sacrifice layer 110B is removed. This step is performed by isotropic etching, such as wet etching.

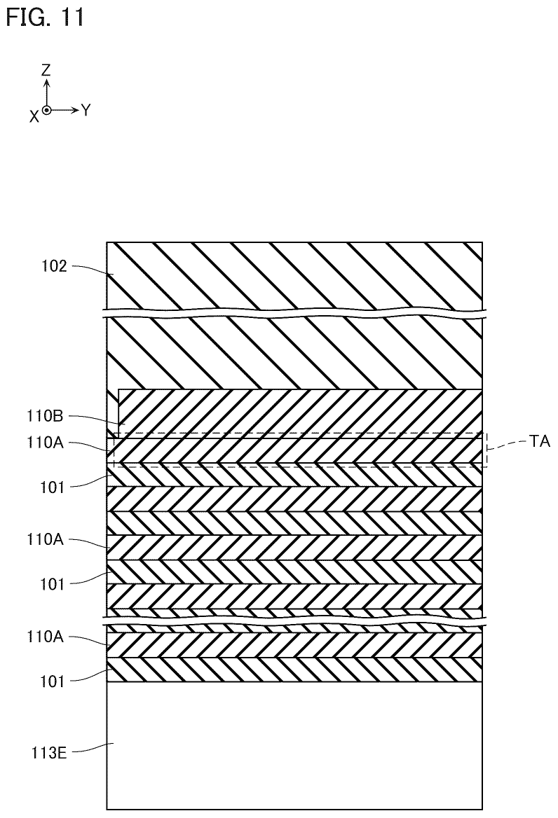

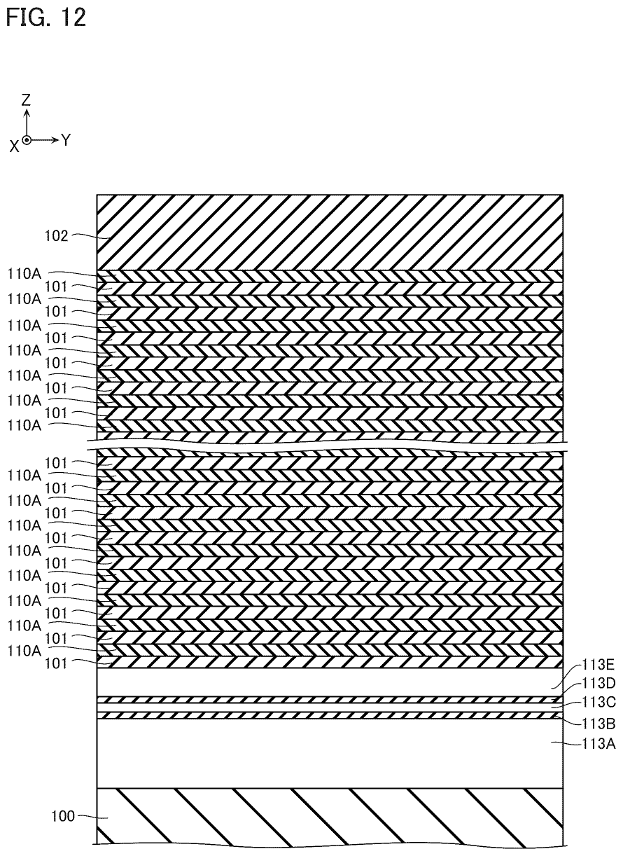

Next, as shown in FIGS. 11 and 12, a part of the insulating layer 102 is formed. This step is performed by a method such as CVD, for example. Note that the insulating layer 102A becomes a part of the insulating layer 102.

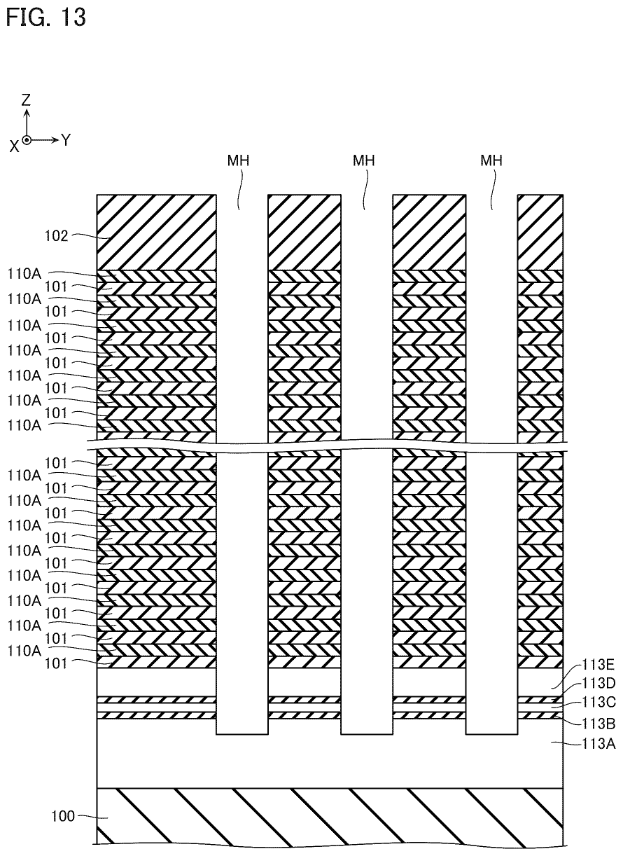

Next, as shown in FIG. 13, for example, memory holes MH are formed at positions corresponding to the semiconductor columns 120. These memory holes MH extend in the Z-direction, penetrate the insulating layer 102, the insulating layers 101 and the sacrifice layers 110A, and the semiconductor layer 113E, the sacrifice layer 113D, the sacrifice layer 113C, and the sacrifice layer 113B, and expose an upper surface of the semiconductor layer 113A. This step is performed by a method such as RIE (Reactive Ion Etching), for example.

Note that though illustration of the following is omitted, in this step, via holes are formed at positions corresponding to the support insulating columns HR (FIG. 6). These via holes extend in the Z-direction, penetrate the insulating layer 102, the insulating layers 101 and sacrifice layers 110A, and the semiconductor layer 113E, sacrifice layer 113D, sacrifice layer 113C, and sacrifice layer 113B, and expose the upper surface of the semiconductor layer 113A. This step is performed by a method such as RIE, for example.

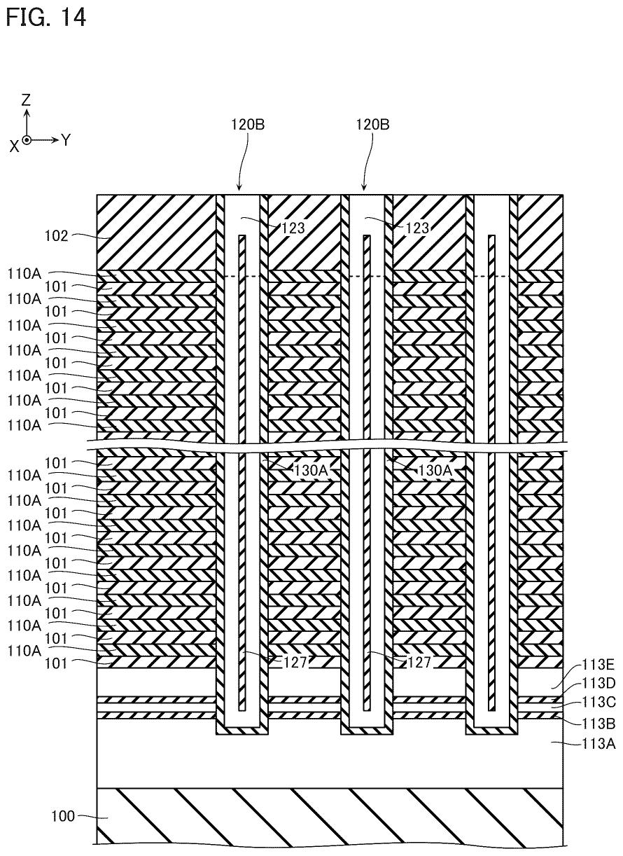

Next, as shown in FIG. 14, for example, insulating films 130A, semiconductor columns 120B, and the insulating columns 127 are formed inside the memory holes MH. The insulating film 130A is basically configured similarly to the gate insulating film 130, but covers an outer peripheral surface of the semiconductor column 120B at height positions of the sacrifice layers 113B, 113C, 113D, too. The semiconductor column 120B is basically configured similarly to the semiconductor column 120, but does not have formed at its lower end portion the region 121 including an N-type impurity. This step is performed by a method such as CVD, for example.

Note that though illustration of the following is omitted, in this step, the support insulating column HR may be formed.

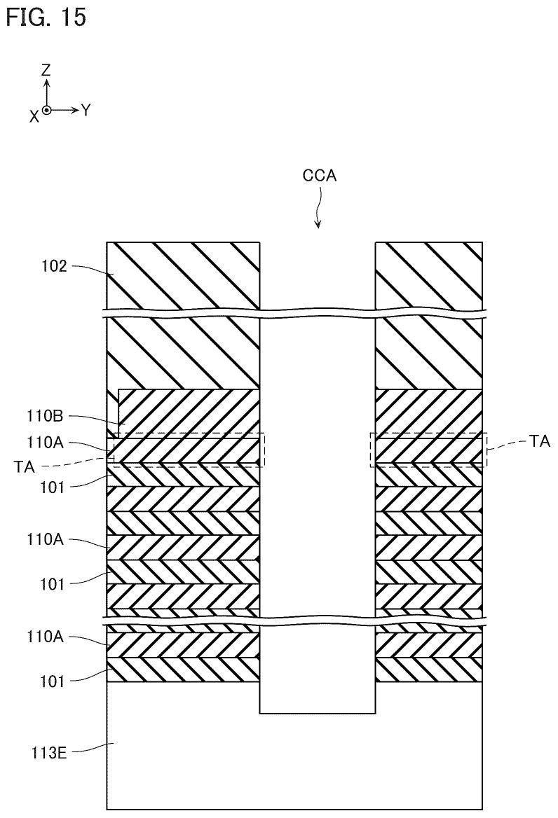

Next, as shown in FIG. 15, for example, a contact hole CCA is formed at a position corresponding to the contact electrode CC. The contact hole CCA extends in the Z-direction, penetrates the insulating layer 102, the sacrifice layer 110B, and the insulating layers 101 and sacrifice layers 110A, and exposes an upper surface of the semiconductor layer 113E. This step is performed by a method such as RIE, for example.

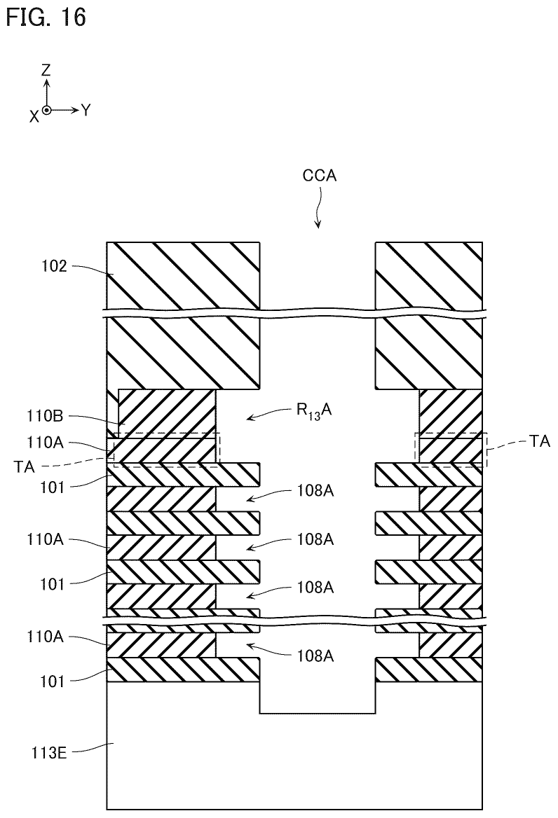

Next, as shown in FIG. 16, for example, parts of the sacrifice layers 110A, 110B are removed via the contact hole CCA. As a result, a recessed portion R₁₃A is formed at a position corresponding to the range R₁₃ (FIG. 8) of the connecting portion R_{C}. In addition, a plurality of recessed portions 108A are formed at positions corresponding to parts of the plurality of insulating layers 108. This step is performed by the likes of wet etching, for example.

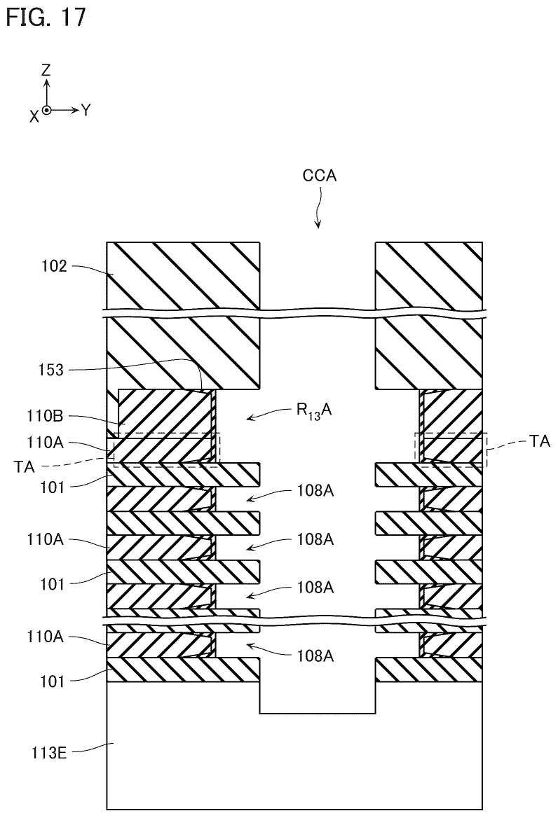

Next, as shown in FIG. 17, for example, surfaces exposed to the contact hole CCA, of the sacrifice layers 110A, 110B are oxidized to form the oxide portions 153. In this step, contact surfaces with the insulating layers 101, 102, of portions provided in a close vicinity to the contact hole CCA of the sacrifice layers 110A, 110B, are also oxidized to become the oxide portions 153. A thickness in the Z-direction of portions formed in contact surfaces with the insulating layers 101, 102, of the oxide portions 153 increases the closer the oxide portions come to the contact hole CCA.

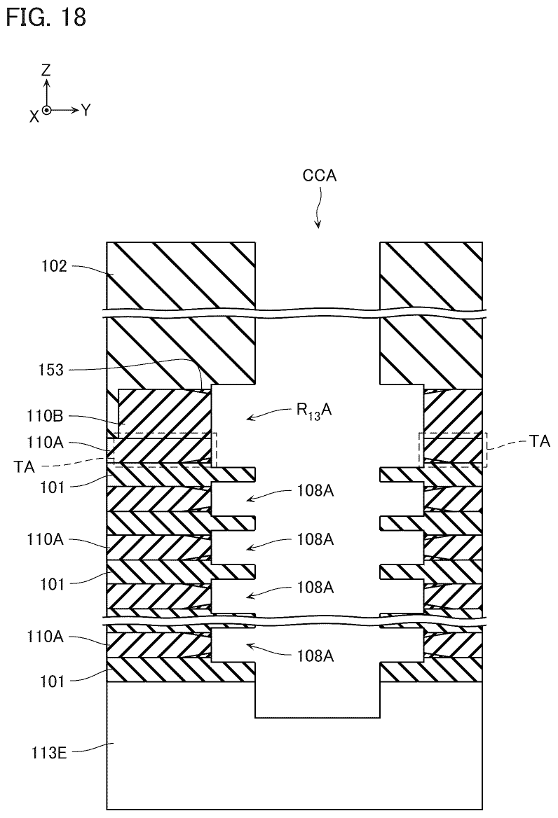

Next, as shown in FIG. 18, for example, parts of the insulating layers 101, a part of the insulating layer 102, and parts of the oxide portions 153 are removed. This step causes the sacrifice layers 110A, 110B to be exposed inside the contact hole CCA. This step is performed by the likes of wet etching, for example.

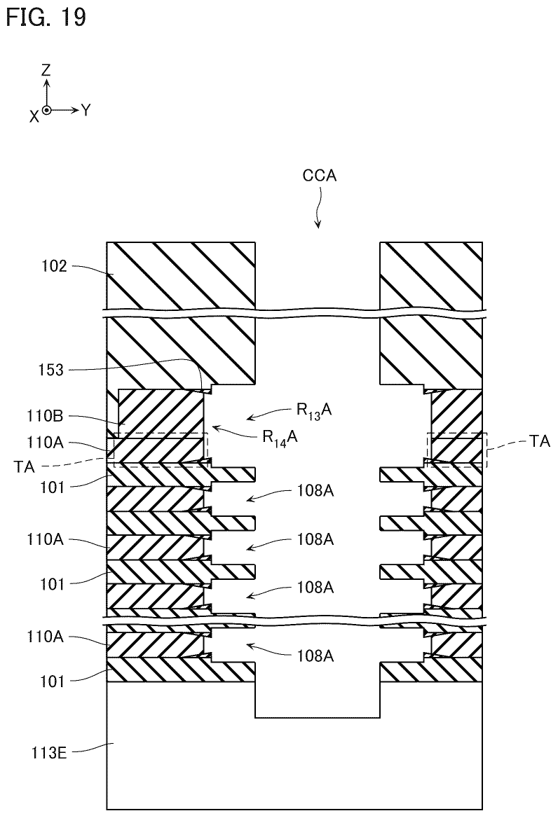

Next, as shown in FIG. 19, for example, parts of the sacrifice layers 110A, 110B exposed within the contact hole CCA are removed. As a result, a recessed portion R₁₄A is formed at a position corresponding to the range R₁₄ (FIG. 8) of the connecting portion R_{C}. In addition, range of the plurality of recessed portions 108A increases. This step is performed by the likes of wet etching, for example.

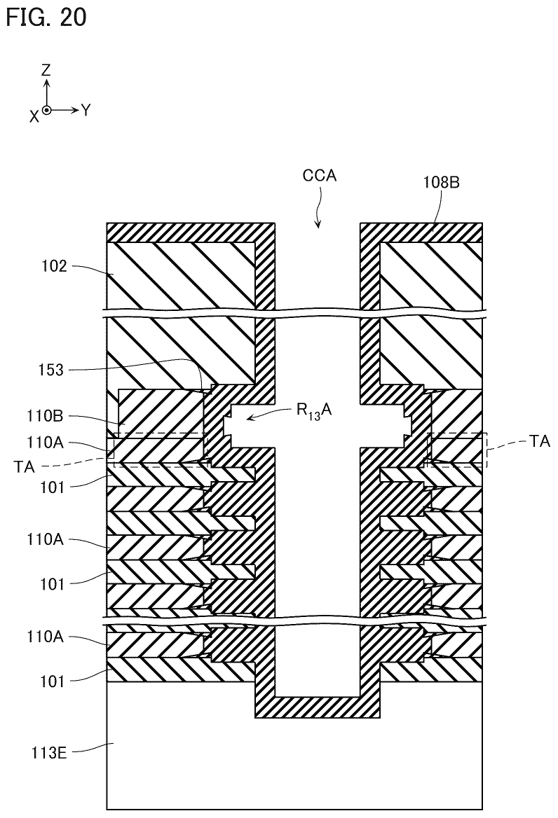

Next, as shown in FIG. 20, for example, an insulating layer 108B is formed on an upper surface of the insulating layer 102, and on inner peripheral surfaces of the plurality of contact holes CCA. At this time, a film thickness of the insulating layer 108B is greater than half the size of a width in the Z-direction of the recessed portion 108A. Hence, the recessed portion 108A is filled in by the insulating layer 108B. On the other hand, the film thickness of the insulating layer 108B is less than half the size of a width in the Z-direction of the recessed portion R₁₃A. Hence, the recessed portion R₁₃A is not filled in by the insulating layer 108B. Moreover, the film thickness of the insulating layer 108B is less than radius of the contact hole CCA. Hence, the contact hole CCA is not filled in by the insulating layer 108B either. This step is performed by a method such as CVD, for example.

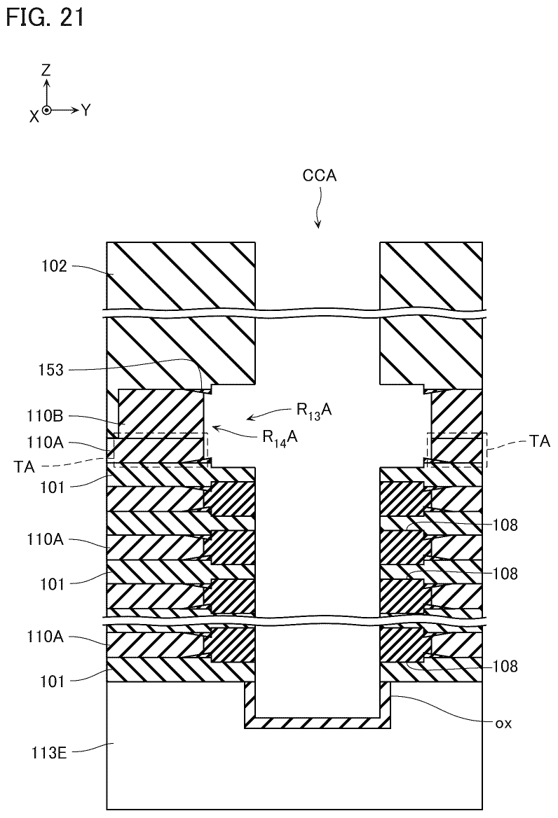

Next, as shown in FIG. 21, for example, a part of the insulating layer 108B is removed. In this step, portions formed on the upper surface of the insulating layer 102, on the inner peripheral surface of the contact hole CCA, and inside the recessed portion R₁₃A and recessed portion R₁₄A, of the insulating layer 108B are removed. As a result, the upper surface of the insulating layer 102, a side surface of the insulating layer 102, the side surfaces of the plurality of insulating layers 101, a side surface of the terrace portion TA of the sacrifice layer 110A, and a side surface of the sacrifice layer 110B are exposed inside the contact hole CCA. In this step, parts of the insulating layer 108B remain at positions corresponding to the plurality of recessed portions 108A, and become the plurality of insulating layers 108. This step is performed by the likes of wet etching, for example.

Next, a bottom portion of the contact hole CCA is oxidized to form the oxide portion ox.

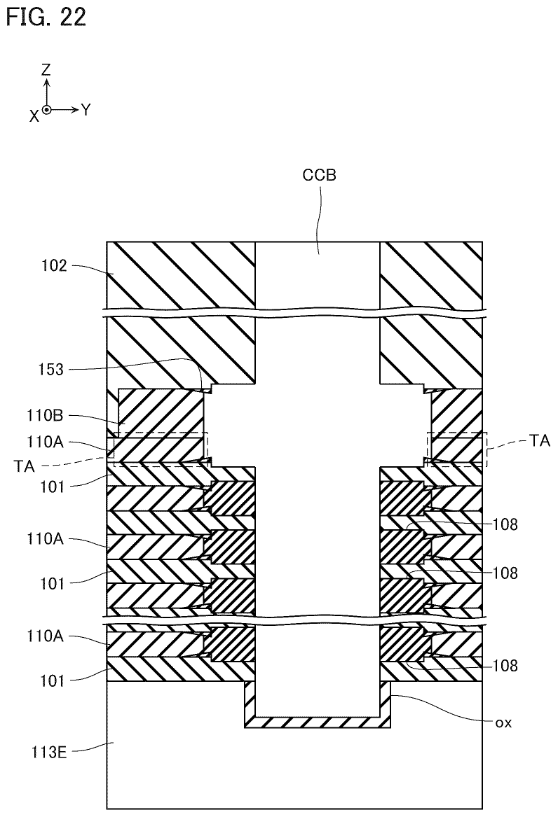

Next, as shown in FIG. 22, for example, a sacrifice layer CCB of the likes of silicon (Si) is formed inside the contact hole CCA. This step is performed by a method such as CVD, for example.

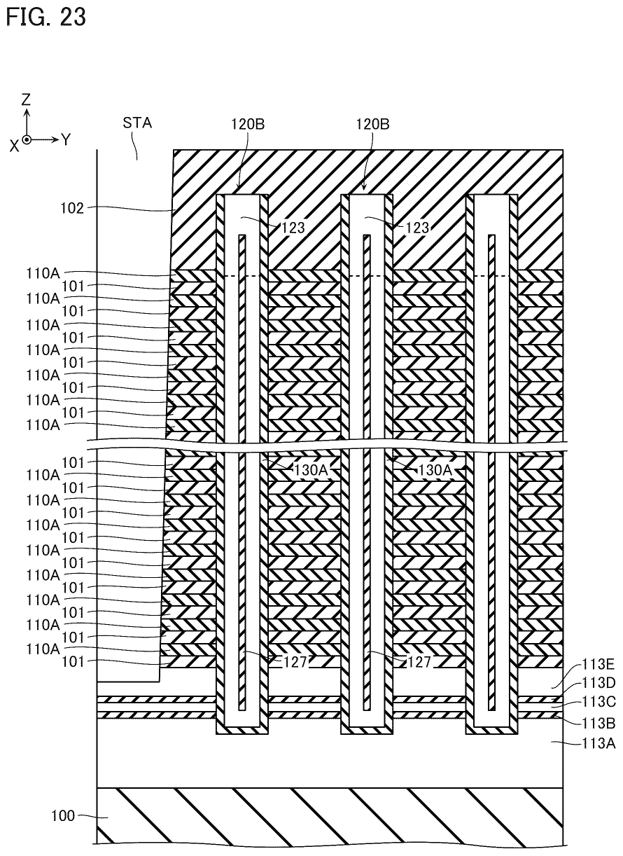

Next, as shown in FIG. 23, for example, a trench STA is formed at a position corresponding to the inter-finger structure ST. The trench STA extends in the Z-direction, penetrates the insulating layer 102 and the insulating layers 101 and sacrifice layers 110A, and exposes the upper surface of the semiconductor layer 113E. This step is performed by a method such as RIE, for example.

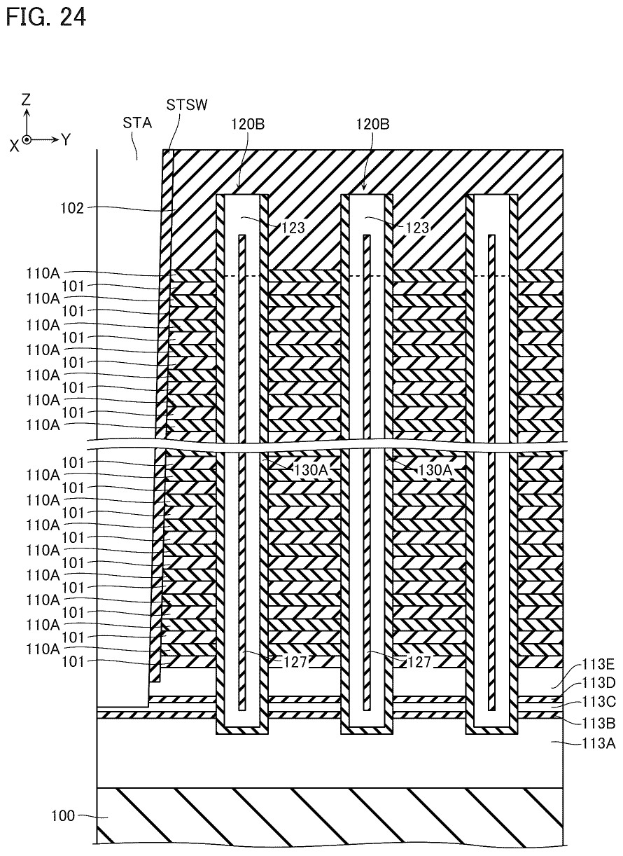

Next, as shown in FIG. 24, for example, a protective film STSW is formed on an inner wall surface and bottom surface of the trench STA, by a method such as CVD. In addition, the protective film STSW, the semiconductor layer 113E, and the sacrifice layer 113D are removed at the bottom surface of the trench STA, by a method such as RIE, to expose the sacrifice layer 113C.

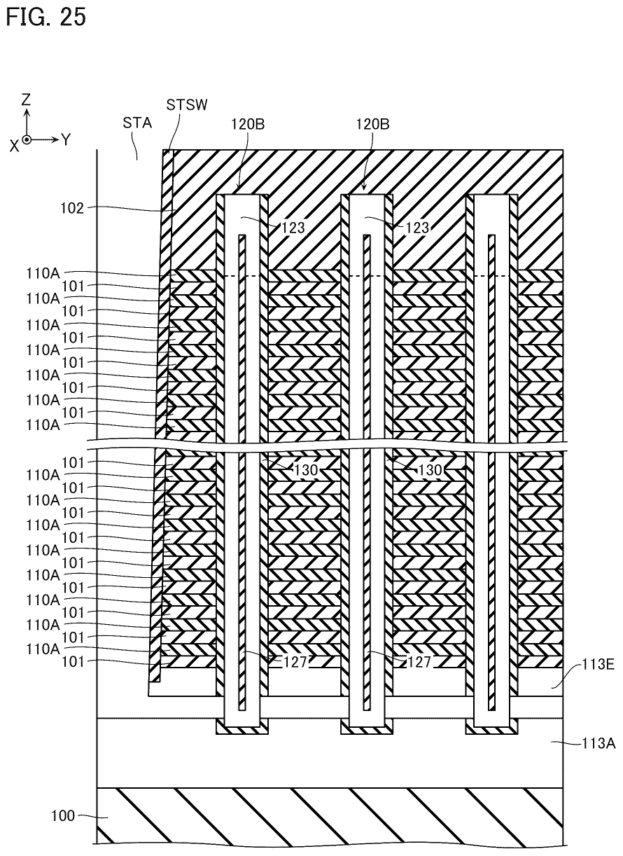

Next, as shown in FIG. 25, for example, the sacrifice layer 113B, the sacrifice layer 113C, the sacrifice layer 113D, and a part of the insulating film 130A are removed. This step is performed by a method such as wet etching, for example. Note that in this step, the gate insulating film 130 is formed.

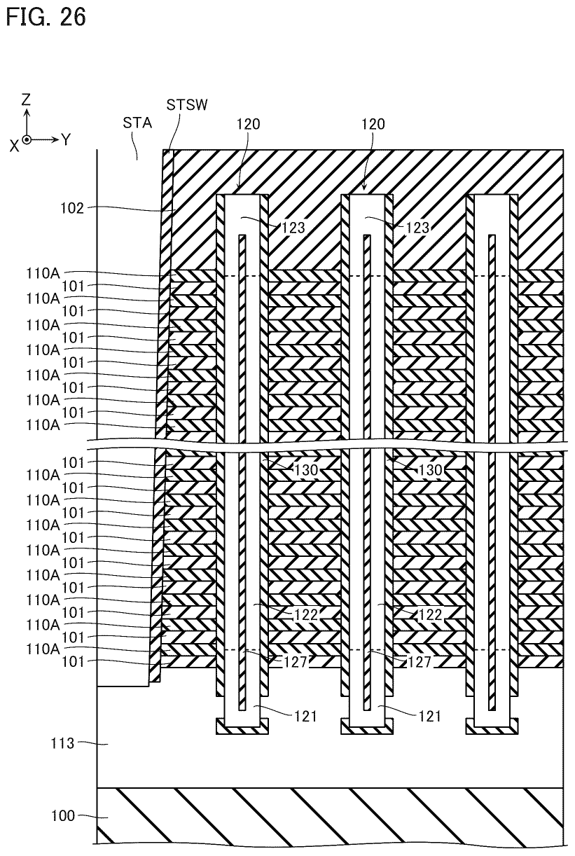

Next, as shown in FIG. 26, for example, the conductive layer 113 is formed. This step is performed by a method such as epitaxial growth, for example. In this step, an N-type impurity is diffused into the lower end portion of the semiconductor column 120B, whereby the semiconductor column 120 is formed.

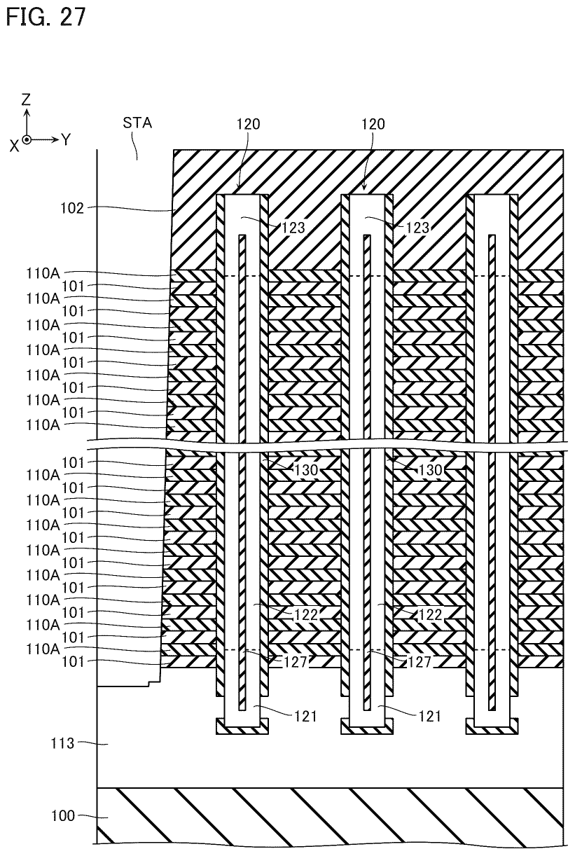

Next, as shown in FIG. 27, for example, the protective film STSW is removed. This step is performed by a method such as wet etching, for example.

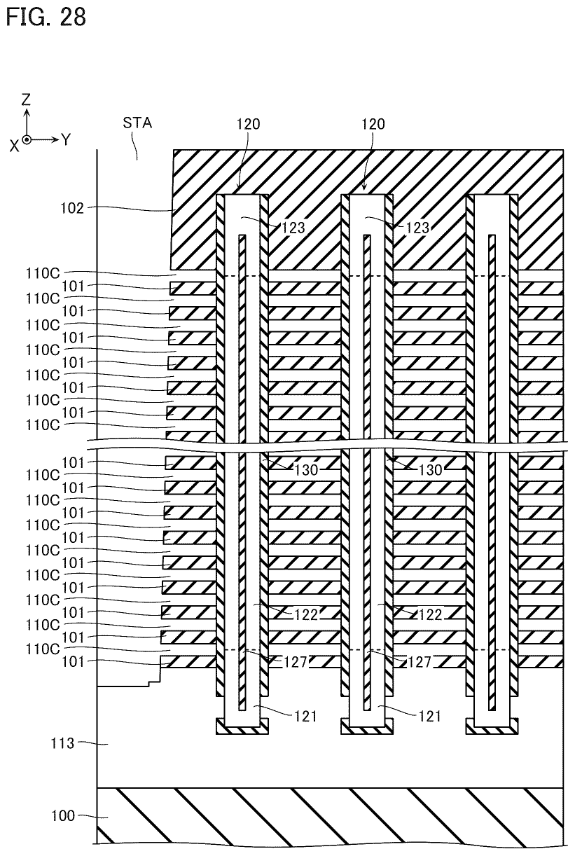

Next, as shown in FIG. 28, for example, the sacrifice layers 110A are removed via the trench STA, and a plurality of cavities 110C are formed. This results in there being formed a hollow structure including: the plurality of insulating layers 101 and the insulating layer 102 arranged in the Z-direction; and the structures in the memory holes MH (semiconductor columns 120, gate insulating films 130, and insulating columns 127), and support insulating columns HR that support these insulating layers 101 and insulating layer 102. Though illustration of the following is omitted, in this step, the sacrifice layer 110B (FIG. 22) is removed too. This step is performed by a method such as wet etching, for example.

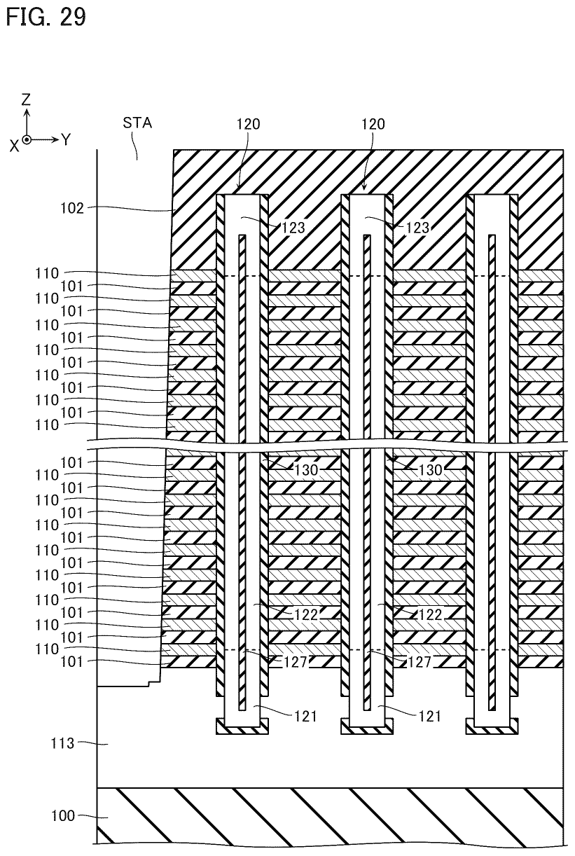

Next, as shown in FIG. 29, for example, the conductive layers 110 are formed in the cavities 110C. This step is performed by a method such as CVD, for example. Note that in this step, the high-dielectric-constant insulating films 104 described with reference to FIG. 5, and so on, are formed before the conductive layers 110 are formed.

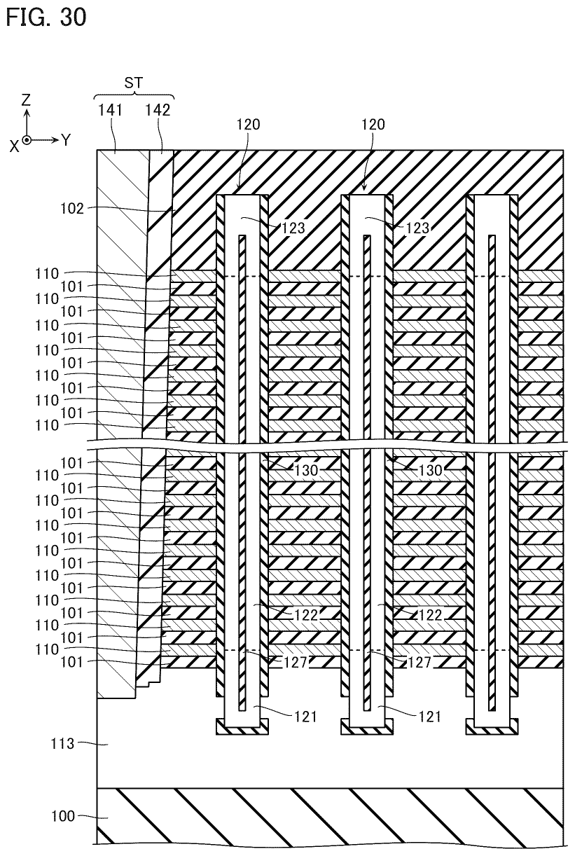

Next, as shown in FIG. 30, for example, the inter-finger structure ST is formed in the trench STA. This step is performed by methods such as CVD and RIE, for example.

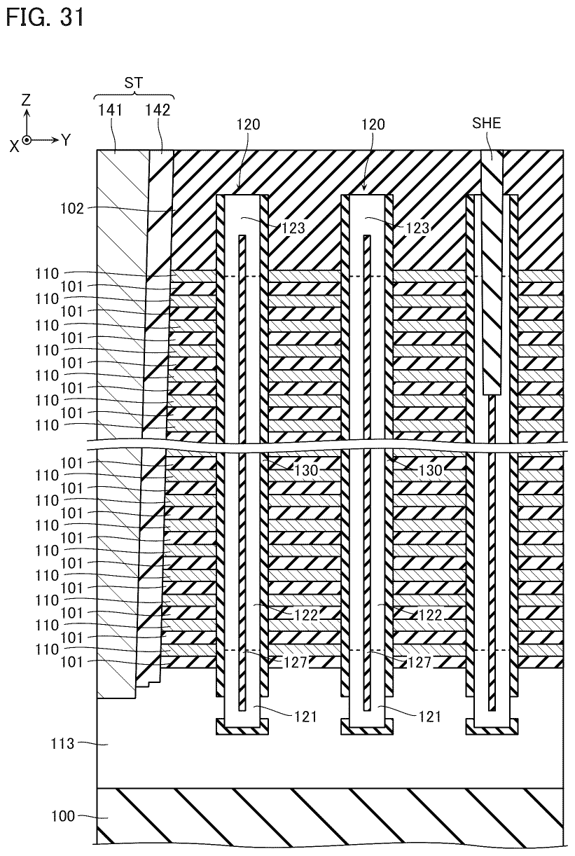

Next, as shown in FIG. 31, for example, the inter-string unit insulating member SHE is formed. This step is performed by methods such as RIE and CVD, for example.

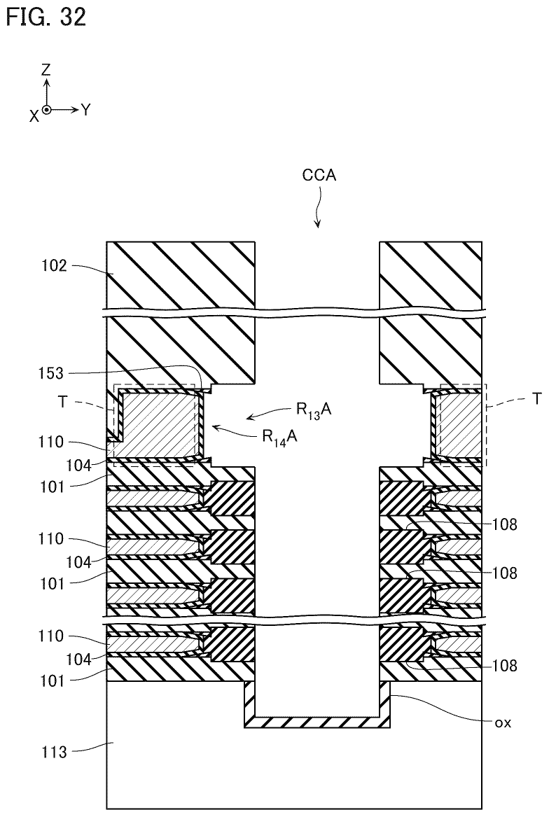

Next, as shown in FIG. 32, for example, the sacrifice layer CCB is removed. As a result, a part of the high-dielectric-constant insulating film 104 is exposed in the contact hole CCA. This step is performed by a method such as wet etching, for example.

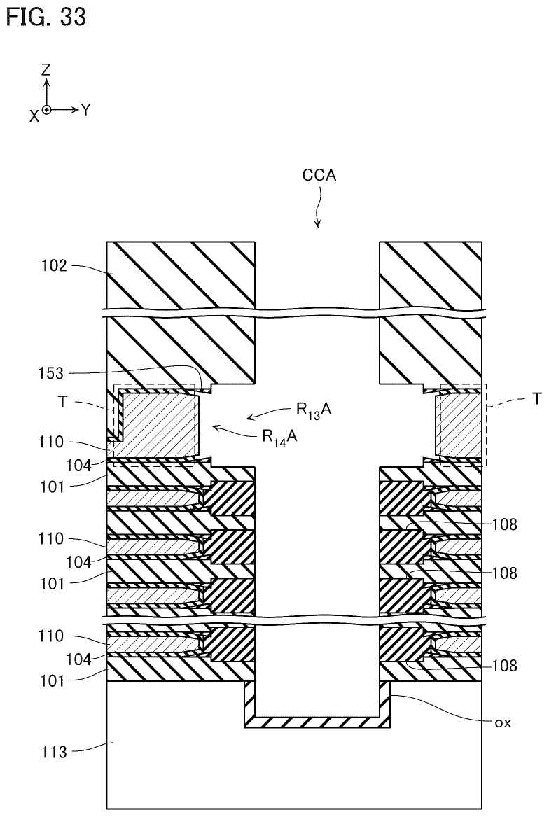

Next, as shown in FIG. 33, for example, a part of the high-dielectric-constant insulating film 104 is removed in the recessed portion R₁₄A. As a result, the side surface of the conductive layer 110 is exposed in the recessed portion R₁₄A. This step is performed by a method such as wet etching, for example.

Next, as shown in FIG. 7, for example, the contact electrode CC is formed inside the contact hole CCA. This step is performed by a method such as CVD, for example. In addition, a part of the insulating layer 102 is formed by a method such as CVD, a contact hole is formed by a method such as RIE, and the contact electrode Ch is formed inside the contact hole by a method such as CVD.

Subsequently, the contact electrode Vy, the bit line BL, and so on, are formed, whereby the semiconductor memory device according to the first embodiment is formed.

### Comparative Example

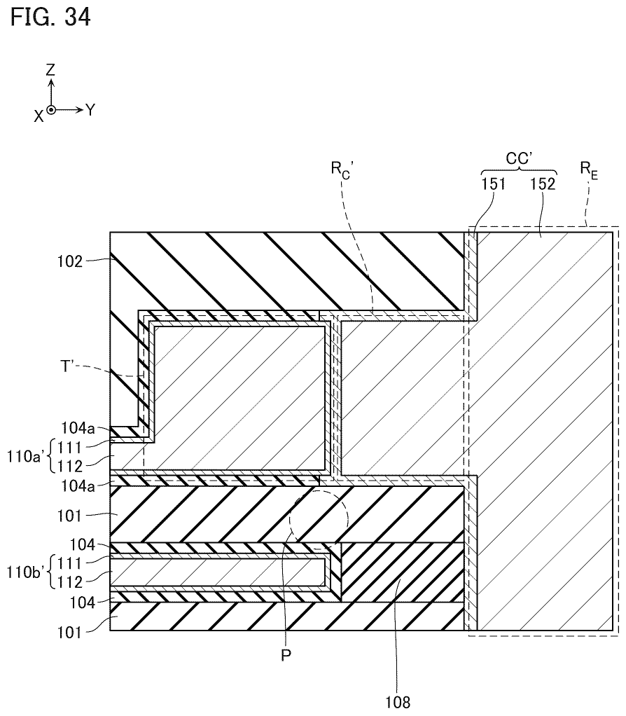

FIG. 34 is a schematic cross-sectional view showing a part of a configuration of a semiconductor memory device according to a comparative example. In FIG. 34, there are illustrated: a contact electrode CC′ according to the comparative example; a conductive layer 110a′ connected to this contact electrode CC′; and a conductive layer 110b′ adjacent to the conductive layer 110a′.

A thickness in the Z-direction of a terrace portion T′ of the conductive layer 110a′ is substantially fixed over the whole of the terrace portion T′. Moreover, in the comparative example, thickness in the Z-direction of a connecting portion R_{C} of the contact electrode CC′ is also substantially fixed over the whole of the connecting portion R_{C}. Moreover, a thickness in the Z-direction of a structure consisting of the conductive layer 110a′, the connecting portion R_{C}′, and the high-dielectric-constant insulating films 104a is also substantially fixed over the whole of a range corresponding to the terrace portion T′ and a range corresponding to the connecting portion R_{C}′.

When manufacturing the semiconductor memory device according to the comparative example, the steps described with reference to FIGS. 17 to 19 are not executed.

In this kind of configuration, basically, an insulating layer 101 and the two high-dielectric-constant insulating films 104 provided on the upper and lower surfaces of this insulating layer 101 are provided between two conductive layers 110 arranged in the Z-direction. However, at a lower surface of a portion connecting the conductive layer 110a′ and the connecting portion R_{C}′, a part of the contact electrode CC′ is provided instead of the high-dielectric-constant insulating film 104. A distance between such a portion and the conductive layer 110b′ is less than distance between the conductive layer 110a′ in another portion and the conductive layer 110b′. Hence, there is concern that a withstand voltage of a portion P between the portion connecting the conductive layer 110a′ and the connecting portion R_{C}′, and the conductive layer 110b′, will decrease.

### Advantages

In the semiconductor memory device according to the first embodiment, as described with reference to FIG. 8, a thickness in the Z-direction of the terrace portion T of the conductive layer 110a decreases the closer the terrace portion T comes to the contact electrode CC in the range R₁₂ from the contact surface with the contact electrode CC of the conductive layer 110a to the position Y₁₁ separated by the distance D11 from the contact electrode CC. Moreover, the end portions on the contact electrode CC side of the high-dielectric-constant insulating films 104a are provided in the above-described range R₁₂. Moreover, a thickness in the Z-direction of the connecting portion R_{C} decreases the closer the connecting portion R_{C} comes to the extending portion R_{E} in the range R₁₄ from the contact surface with the conductive layer 110a of the connecting portion R_{C} to the position Y₁₂ in the Y-direction between this contact surface and the extending portion R_{E}.

Such a configuration enables a lower surface of a portion connecting the conductive layer 110a and the connecting portion R_{C} (the end portion on the contact electrode CC side of the high-dielectric-constant insulating film 104a provided on the lower surface of the conductive layer 110a) to be distanced from the conductive layer 110b. This makes it possible for a withstand voltage of a portion between the portion connecting the conductive layer 110a and the connecting portion R_{C}, and the conductive layer 110b, to be increased.

Moreover, in such a configuration, a thickness in the Z-direction at the end portion on the range R₁₃ side of the range R₁₄, of the connecting portion R_{C} is less than a thickness in the range R₁₃ of the connecting portion R_{C}. Moreover, at the position Y₁₂, the lower surface of the contact electrode CC has the step formed therein.

In such a configuration, there may arise concern that the step formed on the lower surface of the contact electrode CC at the position Y₁₂ is in close proximity to the end portion on the contact electrode CC side of the conductive layer 110b. Due to it being easier for an electric field to concentrate in the end portion on the contact electrode CC side of the conductive layer 110b compared to in the upper and lower surfaces of the conductive layer 110b, it is preferable for the conductive layer 110b and the above-described step to be distanced from each other.

Accordingly, in the semiconductor memory device according to the first embodiment, the step formed on the lower surface of the connecting portion R_{C} at the position Y₁₂ is provided at the contact electrode CC side (an extending portion R_{E} side of the contact electrode CC) with respect to the end portion on the contact electrode CC side of the conductive layer 110b. Such a configuration makes it possible for the end portion on the contact electrode CC side of the conductive layer 110b to be distanced from the above-described step, and for a withstand voltage between them to be thereby increased.

Moreover, in the semiconductor memory device according to the first embodiment, a thickness in the Z-direction of the conductive layer 110b decreases the closer the conductive layer 110b comes to the contact electrode CC in the range R₁₆ from the position separated by the distance D12 from the end portion on the contact electrode CC side of the conductive layer 110b, to the end portion on the contact electrode CC side of the conductive layer 110b.

Such a configuration makes it possible for the conductive layer 110b to be further distanced from the lower surface of the portion connecting the conductive layer 110a and the connecting portion R_{C}, and from the step formed on the lower surface of the connecting portion R_{C} at the position Y₁₂, and for a withstand voltage between them to be thereby further increased.

### Second Embodiment

### [Structure]

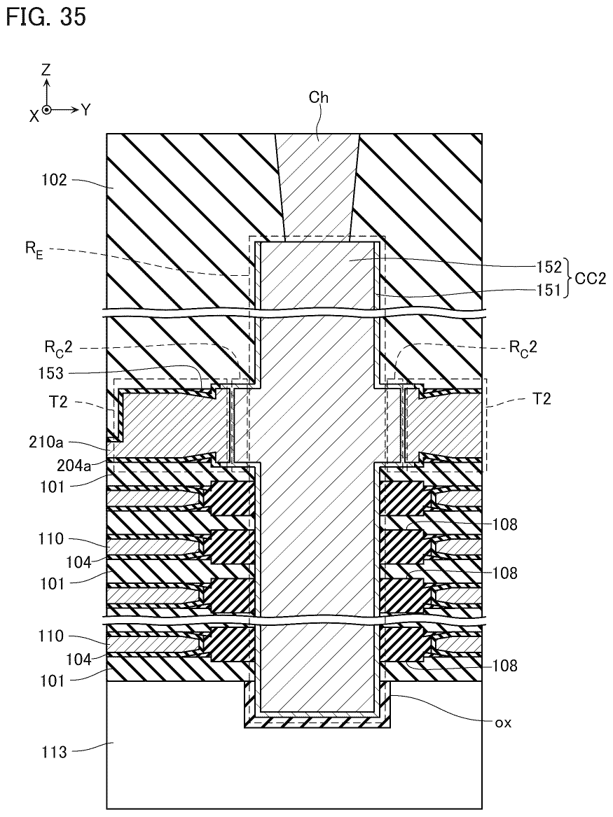

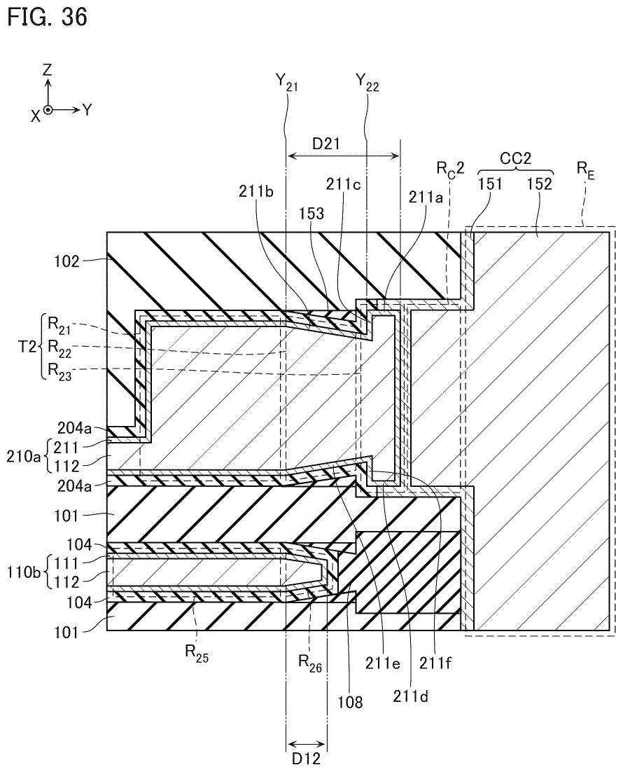

FIGS. 35 and 36 are schematic cross-sectional views showing a part of a configuration of a semiconductor memory device according to a second embodiment. FIG. 36 shows an enlarged part of FIG. 35. Note that although FIG. 36 shows a YZ cross section, a similar structure to in FIG. 36 will be observed, even when a cross section other than a YZ cross section along a central axis of a later-mentioned contact electrode CC2 (for example, an XZ cross section) is observed. In the following description, portions similar to in the first embodiment will be assigned with the same symbols as in the first embodiment, and descriptions thereof omitted.

The semiconductor memory device according to the second embodiment is basically configured similarly to the semiconductor memory device according to the first embodiment. However, the semiconductor memory device according to the second embodiment comprises a conductive layer 210a, high-dielectric-constant insulating films 204a, and a contact electrode CC2, instead of the conductive layer 110a, the high-dielectric-constant insulating films 104a, and the contact electrode CC.

A conductive member consisting of the conductive layer 210a and the contact electrode CC2 comprises a similar configuration to a conductive member consisting of the conductive layer 110a and the contact electrode CC. However, in the first embodiment, a contact surface of the conductive layer 110a and the contact electrode CC is provided in a region corresponding to the oxide portion 153. On the other hand, in the second embodiment, a contact surface of the conductive layer 210a and the contact electrode CC2 is provided at a contact electrode CC2 side with respect to the region corresponding to the oxide portion 153. These configurations will be described in detail below.

The conductive layer 210a is basically configured similarly to the conductive layer 110a. However, the conductive layer 210a comprises a terrace portion T2 instead of the terrace portion T.

The terrace portion T2 is basically configured similarly to the terrace portion T. However, as shown in FIG. 36, a thickness in the Z-direction of the terrace portion T2 of the conductive layer 210a is substantially fixed in a certain range R₂₁ on an opposite side to the contact electrode CC2 with respect to a position Y₂₁ separated by a distance D21 from the contact electrode CC2. Moreover, a thickness in the Z-direction of the terrace portion T2 of the conductive layer 210a is also substantially fixed in a certain range R₂₃ from a contact surface with the contact electrode CC2 of the conductive layer 210a to a position Y₂₂ between the position Y₂₁ and the contact electrode CC2. Moreover, the thickness in the Z-direction of the terrace portion T2 of the conductive layer 210a decreases the closer the terrace portion T2 comes to the contact electrode CC2 in a certain range R₂₂ from the position Y₂₁ to the position Y₂₂. A thickness in the Z-direction at an end portion on a certain range R₂₁ side of the certain range R₂₂, of the terrace portion T2 matches the terrace portion T2's thickness in the Z-direction in the certain range R₂₁. Moreover, a thickness in the Z-direction in the certain range R₂₃ of the terrace portion T2 is greater than a thicknesses in the Z-direction in the certain ranges R₂₁, R₂₂, of the terrace portion T2. At the position Y₂₂, an upper surface and a lower surface of the terrace portion T2 each have a step formed therein.

Moreover, the conductive layer 210a comprises a barrier conductive film 211 instead of the barrier conductive film 111. The barrier conductive film 211 is basically configured similarly to the barrier conductive film 111. However, the barrier conductive film 211 comprises: a film portion 211a covering an upper surface of the metal film 112 in the certain range R₂₃; a film portion 211b covering the upper surface of the metal film 112 in the certain range R₂₂; and a stepped film portion 211c connected to these film portions 211a, 211b between the film portions 211a, 211b. In addition, the barrier conductive film 211 comprises: a film portion 211d covering a lower surface of the metal film 112 in the certain range R₂₃; a film portion 211e covering the lower surface of the metal film 112 in the certain range R₂₂; and a stepped film portion 211f connected to these film portions 211d, 211e between the film portions 211d, 211e.

The contact electrode CC2 is basically configured similarly to the contact electrode CC. However, the contact electrode CC2 comprises a connecting portion R_{C}2 instead of the connecting portion R_{C}. In the present embodiment, a thickness in the Z-direction of the connecting portion R_{C}2 is substantially fixed over the whole of the connecting portion R_{C}2.

The high-dielectric-constant insulating film 204a is basically configured similarly to the high-dielectric-constant insulating film 104a. However, an end portion on a contact electrode CC2 side of the high-dielectric-constant insulating film 204a is provided in the above-described certain range R₂₃. Moreover, a thickness in the Z-direction of a structure consisting of the conductive layer 210a and the high-dielectric-constant insulating films 204a decreases the closer the structure comes to the contact electrode CC2 in the above-described certain range R₂₂.

Moreover, as shown in FIG. 36, in the certain range R₂₂, upper and lower surfaces of the high-dielectric-constant insulating films 204a are each provided with the oxide portion 153. A thickness in the Z-direction of a structure consisting of the conductive layer 210a, the high-dielectric-constant insulating films 204a, and the oxide portions 153 are substantially fixed over the above-described certain ranges R₂₁, R₂₂. Note that a thickness in the Z-direction of the connecting portion R_{C}2 is greater than a thickness in the Z-direction of this structure.

Moreover, FIG. 36 illustrates certain ranges R₂₅, R₂₆ of the conductive layer 110b. A structure in the certain ranges R₂₅, R₂₆ of the conductive layer 110b is similar to a structure in the ranges R₁₅, R₁₆ (FIG. 8) of the conductive layer 110b. In the present embodiment, the position Y₂₁ separated by the distance D21 from the contact electrode CC2 of the conductive layer 210a and the position separated by the distance D12 from the end portion on a contact electrode CC2 side of the conductive layer 110b substantially match, viewed in the Z-direction. Moreover, the contact surface with the contact electrode CC2 of the conductive layer 210a is provided at a contact electrode CC2 side with respect to the end portion on a contact electrode CC2 side of the conductive layer 110b.

Moreover, in the present embodiment, the steps formed on the upper surface and the lower surface of the terrace portion T2 at the position Y₂₂ are provided at a contact electrode CC2 side with respect to the end portion on a contact electrode CC2 side of the conductive layer 110b.

### [First Method of Manufacturing]

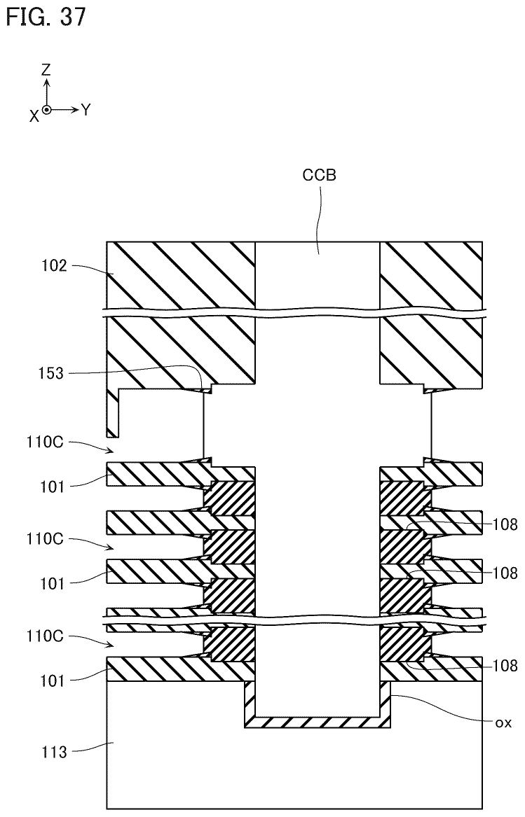

Next, a first method of manufacturing the semiconductor memory device according to the second embodiment will be described with reference to FIGS. 37 to 41. FIGS. 37 to 41 are schematic cross-sectional views for explaining the method of manufacturing. FIGS. 37 to 41 show cross sections corresponding to FIG. 35.

In the first method of manufacturing the semiconductor memory device according to the second embodiment, steps up to the step described with reference to FIG. 28, of the method of manufacturing the semiconductor memory device according to the first embodiment, are executed. As a result, the sacrifice layer CCB is exposed inside the cavity 110C, as shown in FIG. 37.

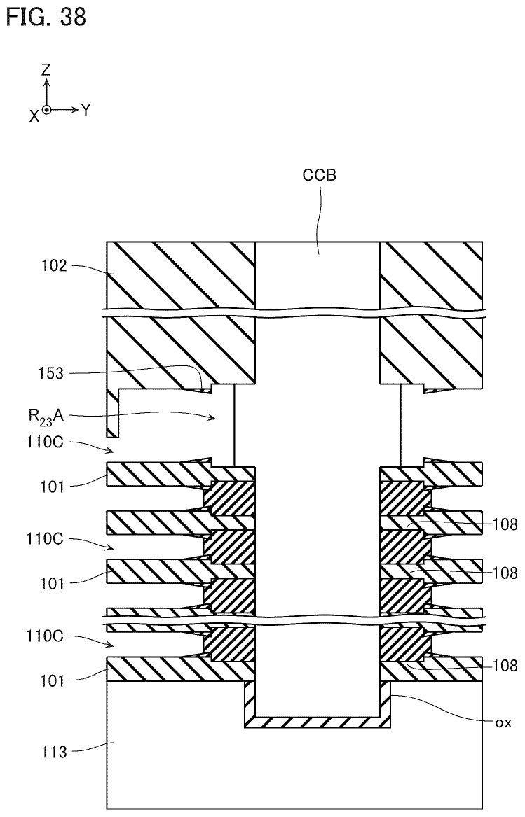

Next, as shown in FIG. 38, a portion provided at a position corresponding to the certain range R₂₃ of the terrace portion T2, of the sacrifice layer CCB is removed. As a result, a cavity R₂₃A is formed at the position corresponding to the certain range R₂₃. This step is performed by the likes of wet etching, for example.

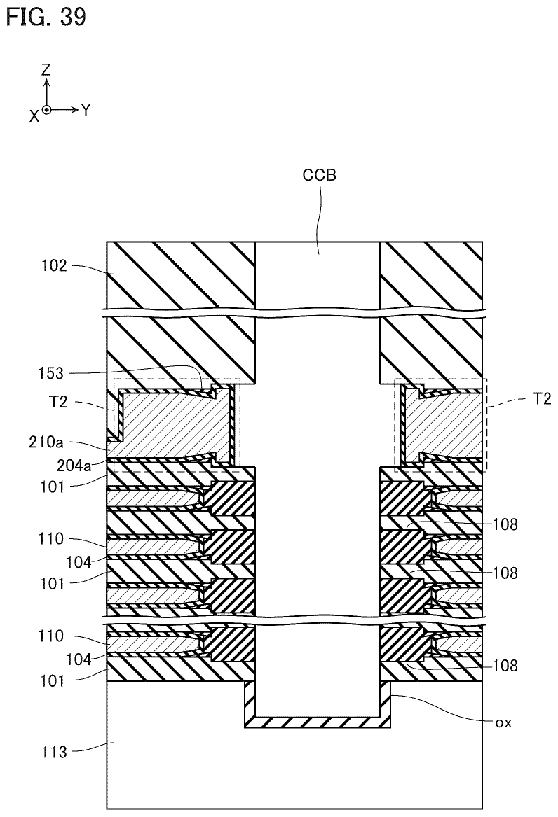

Next, as shown in FIG. 39, for example, the high-dielectric-constant insulating films 104, 204a and the conductive layers 110, 210a are formed in the cavities 110C. As a result, the high-dielectric-constant insulating film 204a and the conductive layer 210a are also formed in the cavity R₂₃A communicating with the cavity 110C. This step is executed similarly to the step described with reference to FIG. 29.

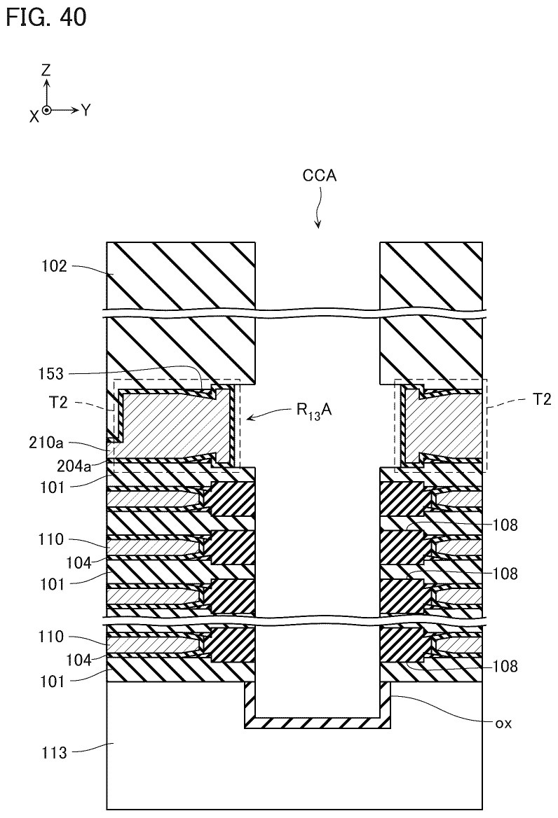

Next, the steps described with reference to FIGS. 30 to 32 are executed. As a result, a part of the high-dielectric-constant insulating film 204a is exposed in the contact hole CCA, as shown in FIG. 40.

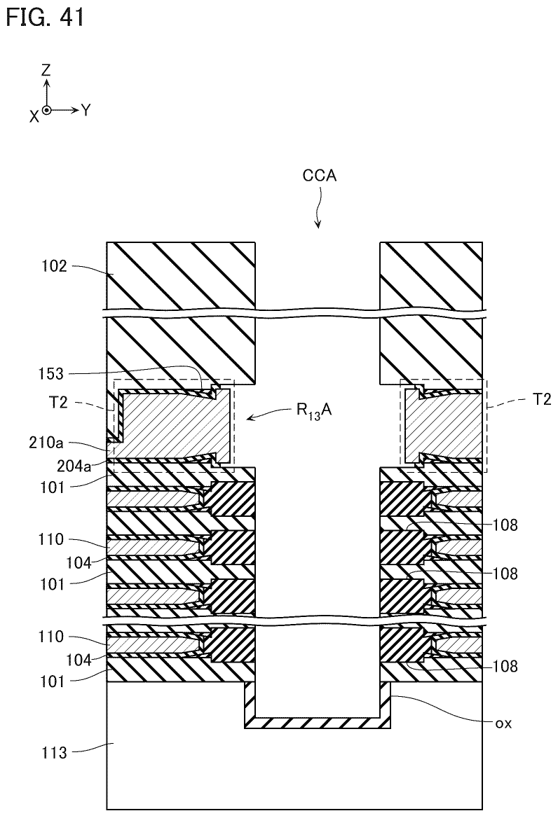

Next, as shown in FIG. 41, for example, a part of the high-dielectric-constant insulating film 204a is removed in the recessed portion R₁₃A. As a result, a side surface of the conductive layer 210a is exposed in the recessed portion R₁₃A. This step is performed by a method such as wet etching, for example.

Next, as shown in FIG. 35, for example, the contact electrode CC2 is formed inside the contact hole CCA. This step is performed by a method such as CVD, for example. In addition, a part of the insulating layer 102 is formed by a method such as CVD, a contact hole is formed by a method such as RIE, and the contact electrode Ch is formed inside the contact hole by a method such as CVD.

Subsequently, the contact electrode Vy, the bit line BL, and so on, are formed, whereby the semiconductor memory device according to the second embodiment is formed.

### [Second Method of Manufacturing]

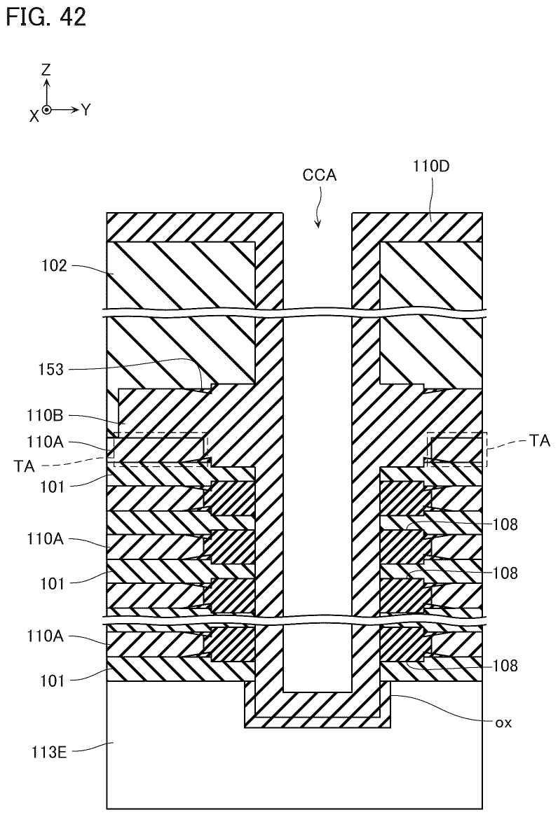

Next, a second method of manufacturing the semiconductor memory device according to the second embodiment will be described with reference to FIGS. 42 to 44. FIGS. 42 to 44 are schematic cross-sectional views for explaining the method of manufacturing. FIGS. 42 to 44 show cross sections corresponding to FIG. 35.

In the second method of manufacturing the semiconductor memory device according to the second embodiment, steps up to the step described with reference to FIG. 21, of the method of manufacturing the semiconductor memory device according to the first embodiment, are executed.

Next, as shown in FIG. 42, a sacrifice layer 110D is formed on the upper surface of the insulating layer 102, and on the inner peripheral surfaces of the plurality of contact holes CCA. At this time, a film thickness of the sacrifice layer 110D is greater than half the size of the width in the Z-direction of the recessed portion R₁₃A. Hence, the recessed portion R₁₃A is filled in by the sacrifice layer 110D. On the other hand, the film thickness of the sacrifice layer 110D is less than radius of the contact hole CCA. Hence, the contact hole CCA is not filled in by the sacrifice layer 110D. This step is performed by a method such as CVD, for example.

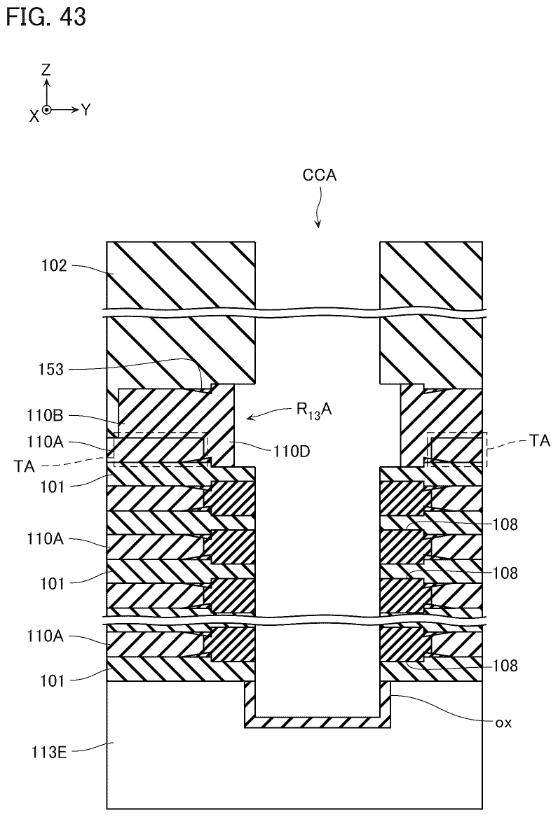

Next, as shown in FIG. 43, for example, a part of the sacrifice layer 110D is removed. In this step, a portion formed on the upper surface of the insulating layer 102, a portion formed on the inner peripheral surface of the contact hole CCA, and a part of a portion formed inside the recessed portion R₁₃A, of the sacrifice layer 110D are removed. As a result, the upper surface of the insulating layer 102, the side surface of the insulating layer 102, side surfaces of the plurality of insulating layers 101, and side surfaces of the plurality of insulating layers 108 are exposed inside the contact hole CCA. In this step, a part of the sacrifice layer 110D is left at a position corresponding to the certain range R₂₃ (FIG. 36) of the terrace portion T2. This step is performed by the likes of wet etching, for example.

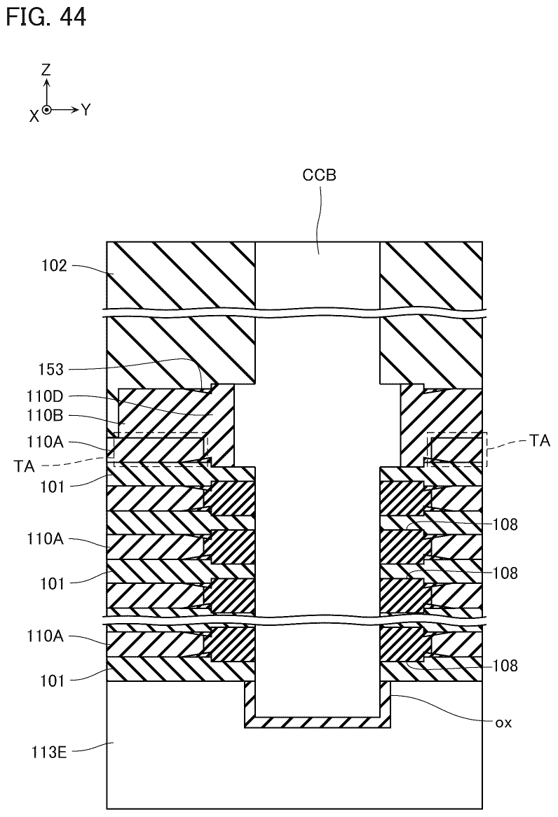

Next, as shown in FIG. 44, for example, a sacrifice layer CCB of the likes of silicon (Si) is formed inside the contact hole CCA. This step is performed by a method such as CVD, for example.

Next, the steps described with reference to FIGS. 23 to 32, of the method of manufacturing the semiconductor memory device according to the first embodiment, are executed. As a result, a structure of the kind shown in FIG. 40 is formed.

Subsequently, steps from the step described with reference to FIG. 41 onward, of the first method of manufacturing the semiconductor memory device according to the second embodiment, are executed, whereby the semiconductor memory device according to the second embodiment is formed.

### Advantages

In the semiconductor memory device according to the second embodiment, as described with reference to FIG. 36, the contact surface with the contact electrode CC2 of the conductive layer 210a is provided at the contact electrode CC2 side with respect to the end portion on the contact electrode CC2 side of the conductive layer 110b. Moreover, the end portions on the contact electrode CC2 side of the high-dielectric-constant insulating films 204a are provided in the above-described certain range R₂₃.

Such a configuration enables a lower surface of a portion connecting the conductive layer 210a and the connecting portion R_{C}2 (the end portion on the contact electrode CC2 side of the high-dielectric-constant insulating film 204a) to be distanced from the conductive layer 110b. This makes it possible for a withstand voltage of a portion between the portion connecting the conductive layer 210a and the connecting portion R_{C}2, and the conductive layer 110b, to be increased.

Moreover, in such a configuration, a thickness in the Z-direction in the certain range R₂₃ of the terrace portion T2 is greater than a thicknesses in the Z-direction in the certain ranges R₂₁, R₂₂, of the terrace portion T2. Moreover, at the position Y₂₂, the lower surface of the terrace portion T2 has the step formed therein.

In such a configuration, there may arise concern that the step formed on the lower surface of the terrace portion T2 at the position Y₂₂ is in close proximity to the conductive layer 110b.

Accordingly, in the second embodiment, the step formed on the lower surface of the terrace portion T2 at the position Y₂₂ is provided at the contact electrode CC2 side with respect to the end portion on the contact electrode CC2 side of the conductive layer 110b. Such a configuration makes it possible for the end portion on the contact electrode CC2 side of the conductive layer 110b to be distanced from the above-described step, and for a withstand voltage between them to be thereby increased.

Furthermore, in the present embodiment, the end portions on the contact electrode CC2 side of the high-dielectric-constant insulating films 204a are provided in the certain range R₂₃. That is, the above-described step formed on the lower surface of the conductive layer 210a is covered by the high-dielectric-constant insulating film 204a. This makes it possible for the step formed on the lower surface of the terrace portion T2 at the position Y₂₂, and the conductive layer 110b, to be further distanced from each other, and for a withstand voltage between them to be thereby further increased.

Moreover, in the semiconductor memory device according to the present embodiment, similarly to in the semiconductor memory device according to the first embodiment, a thickness in the Z-direction of the conductive layer 110b decreases the closer the conductive layer 110b comes to the contact electrode CC2 in the certain range R₂₆ from the position separated by the distance D12 from the end portion on the contact electrode CC2 side of the conductive layer 110b, to the end portion on the contact electrode CC2 side of the conductive layer 110b.

Such a configuration makes it possible for the conductive layer 110b to be further distanced from the step formed on the lower surface of the terrace portion T2 at the position Y₂₂, and for a withstand voltage between them to be thereby further increased.

### Third Embodiment

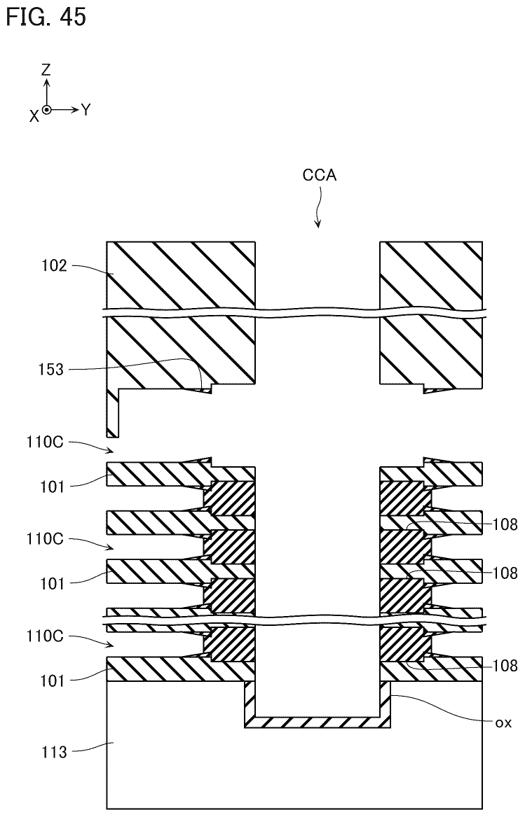

Next, a semiconductor memory device according to a third embodiment will be described. FIG. 45 is a schematic cross-sectional view for explaining a method of manufacturing the semiconductor memory device according to the third embodiment.

The semiconductor memory device according to the third embodiment is basically manufactured similarly to the semiconductor memory device according to the first embodiment. However, when manufacturing the semiconductor memory device according to the third embodiment, as shown in FIG. 45, the sacrifice layer CCB is removed after execution of the step described with reference to FIG. 28, but before execution of the step described with reference to FIG. 29. Moreover, in the step described with reference to FIG. 29, the conductive layer 110, and so on, and a structure corresponding to the contact electrode CC, are formed simultaneously.

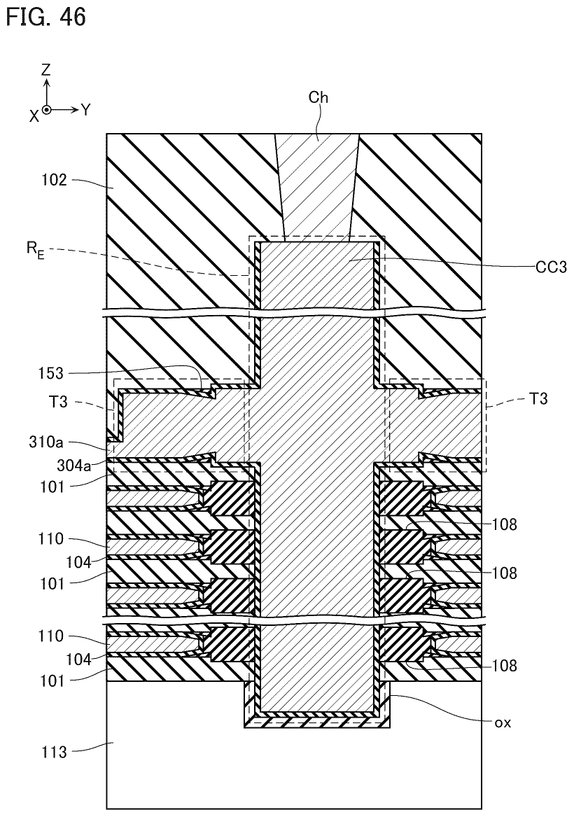

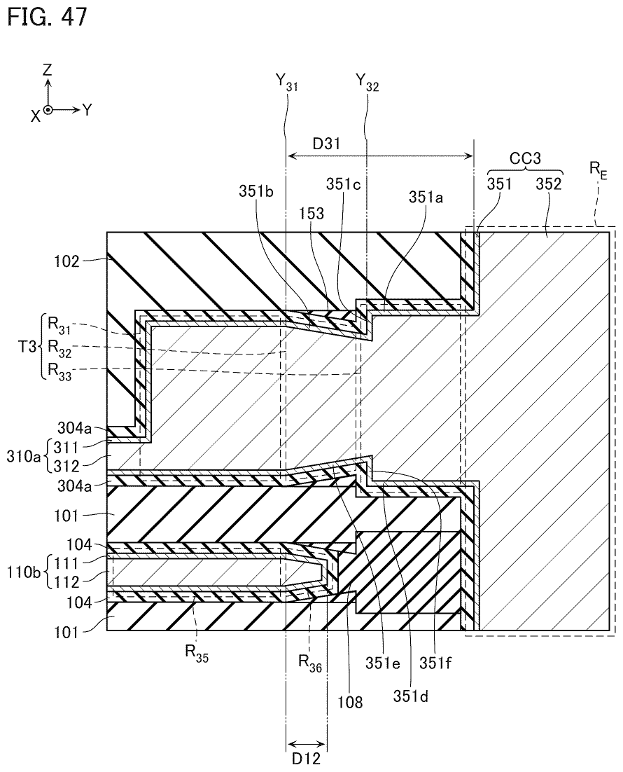

FIGS. 46 and 47 are schematic cross-sectional views showing a part of a configuration of the semiconductor memory device according to the third embodiment. FIG. 47 shows an enlarged part of FIG. 46. Note that although FIG. 47 shows a YZ cross section, a similar structure to in FIG. 47 will be observed, even when a cross section other than a YZ cross section along a central axis of a later-mentioned contact electrode CC3 (for example, an XZ cross section) is observed. In the following description, portions similar to in the first embodiment will be assigned with the same symbols as in the first embodiment, and descriptions thereof omitted.

The semiconductor memory device according to the third embodiment is basically configured similarly to the semiconductor memory device according to the first embodiment. However, the semiconductor memory device according to the third embodiment comprises a conductive layer 310a, a high-dielectric-constant insulating film 304a, and a contact electrode CC3, instead of the conductive layer 110a, the high-dielectric-constant insulating film 104a, and the contact electrode CC.

A conductive member consisting of the conductive layer 310a and the contact electrode CC3 comprises a similar configuration to a conductive member consisting of the conductive layer 110a and the contact electrode CC. However, in the third embodiment, as mentioned above, in the step described with reference to FIG. 29, the conductive layer 110, and so on, and the structure corresponding to the contact electrode CC, are formed simultaneously. Therefore, in the third embodiment, the conductive layer 310a and the contact electrode CC3 are continuous, and do not have a contact surface provided between them. These configurations will be described in detail below.

The conductive layer 310a is basically configured similarly to the conductive layer 110a. However, the conductive layer 310a comprises a barrier conductive film 311 and a metal film 312, instead of the barrier conductive film 111 and the metal film 112.

The contact electrode CC3 is basically configured similarly to the contact electrode CC. However, the contact electrode CC3 comprises a barrier conductive film 351 and a metal film 352, instead of the barrier conductive film 151 and the metal film 152.

The barrier conductive films 311, 351 and the metal films 312, 352 are basically configured similarly to the barrier conductive films 111, 151 and the metal films 112, 152. However, the barrier conductive film 311 and barrier conductive film 351 are formed simultaneously in the step described with reference to FIG. 29. Therefore, the barrier conductive film 311 is continuous with the barrier conductive film 351. Similarly, the metal film 312 and the metal film 352 are formed simultaneously in the step described with reference to FIG. 29. Therefore, the metal film 312 is continuous with the metal film 352. Moreover, the barrier conductive film 351 has a similar film thickness to the barrier conductive film 311.

A portion that, viewed from above, does not overlap another conductive layer 110, and that excludes the extending portion R_{E}, of the conductive member consisting of the conductive layer 310a and the contact electrode CC3, is shown in FIGS. 46 and 47 as a terrace portion T3.

A thickness in the Z-direction of the terrace portion T3 is substantially fixed in a region R₃₁ on an opposite side to the extending portion R_{E} with respect to a position Y₃₁ separated by a distance D31 from the extending portion R_{E}. Moreover, a thickness in the Z-direction of the terrace portion T3 is also substantially fixed in a region R₃₃ from the extending portion R_{E} to a position Y₃₂ between the extending portion R_{E} and the position Y₃₁. Moreover, the thickness in the Z-direction of the terrace portion T3 decreases the closer the terrace portion T3 comes to the extending portion R_{E} in a region R₃₂ from the position Y₃₁ to the position Y₃₂. Thickness in the Z-direction at an end portion on a region R₃₁ side of the region R₃₂, of the terrace portion T3 matches a thickness in the region R₃₁ of the terrace portion T3. Moreover, the thickness in the Z-direction in the region R₃₃ of the terrace portion T3 is greater than the thicknesses in the Z-direction in the regions R₃₁, R₃₂, of the terrace portion T3. At the position Y₃₂, an upper surface and a lower surface of the terrace portion T3 each have a step formed therein.

Moreover, the barrier conductive film 351 comprises: a film portion 351a covering an upper surface of the metal film 352 in the region R₃₃; a film portion 351b covering the upper surface of the metal film 352 in the region R₃₂; and a stepped film portion 351c connected to these film portions 351a, 351b between the film portions 351a, 351b. In addition, the barrier conductive film 351 comprises: a film portion 351d covering a lower surface of the metal film 352 in the region R₃₃; a film portion 351e covering the lower surface of the metal film 352 in the region R₃₂; and a stepped film portion 351f connected to these film portions 351d, 351e between the film portions 351d, 351e.

The high-dielectric-constant insulating films 304a are basically configured similarly to the high-dielectric-constant insulating films 104a. However, the high-dielectric-constant insulating films 304a cover the upper and lower surfaces of the terrace portion T3 over the whole of the terrace portion T3, and, furthermore, also covers an outer peripheral surface of the extending portion R_{E} of the contact electrode CC3.

Moreover, in the region R₃₂, upper and lower surfaces of the high-dielectric-constant insulating films 304a are each provided with the oxide portion 153. A thickness in the Z-direction of a structure consisting of the terrace portion T3, the high-dielectric-constant insulating films 304a, and the oxide portions 153 are substantially fixed over the above-described regions R₃₁, R₃₂. Note that a thickness in the Z-direction in the region R₃₃, of the structure consisting of the terrace portion T3, the high-dielectric-constant insulating films 304a, and the oxide portions 153 is greater than the structure's thickness in the Z-direction in the regions R₃₁, R₃₂.

Moreover, FIG. 47 illustrates regions R₃₅, R₃₆ of the conductive layer 110b. A structure in the regions R₃₅, R₃₆ of the conductive layer 110b is similar to a structure in the ranges R₁₅, R₁₆ of the conductive layer 110b. In the present embodiment, the position Y₃₁ separated by the distance D31 from the extending portion R_{E} of the terrace portion T3 and the position separated by the distance D12 from the end portion on an extending portion R_{E} side of the conductive layer 110b substantially match, viewed in the Z-direction.

Moreover, in the present embodiment, the steps formed on the upper surface and the lower surface of the terrace portion T3 at the position Y₃₂ are provided at an extending portion R_{E} side with respect to the end portion on an extending portion R_{E} side of the conductive layer 110b.

### Advantages

In the third embodiment, the conductive layer 310a and the contact electrode CC3 are continuous with each other. Moreover, the high-dielectric-constant insulating films 304a covers the upper and lower surfaces of the terrace portion T3 over the whole of the terrace portion T3, and, furthermore, also covers the outer peripheral surface of the extending portion R_{E} of the contact electrode CC3. In such a configuration, the problem of a withstand voltage degrading in the portion P between the portion connecting the conductive layer 110a′ and the connecting portion R_{C}′, and the conductive layer 110b′, of the kind described with reference to FIG. 34, does not occur.

Moreover, in such a configuration, a thickness in the Z-direction in the region R₃₃ of the terrace portion T3 is greater than the thicknesses in the Z-direction in the regions R₃₁, R₃₂, of the terrace portion T3. Moreover, at the position Y₃₂, the lower surface of the terrace portion T3 has the step formed therein.

In such a configuration, there may arise concern that the step formed on the lower surface of the terrace portion T3 at the position Y₃₂ is in close proximity to the conductive layer 110b.

Accordingly, in the third embodiment, the step formed on the lower surface of the terrace portion T3 at the position Y₃₂ is provided at the extending portion R_{E} side with respect to the end portion on the extending portion R_{E} side of the conductive layer 110b. Such a configuration makes it possible for the end portion on the extending portion R_{E} side of the conductive layer 110b to be distanced from the above-described step, and for a withstand voltage between them to be thereby increased.

Moreover, in the semiconductor memory device according to the present embodiment, similarly to in the semiconductor memory devices according to the first embodiment and the second embodiment, a thickness in the Z-direction of the conductive layer 110b decreases the closer the conductive layer 110b comes to the extending portion R_{E} in the region R₃₆ from the position separated by the distance D12 from the end portion on the extending portion R_{E} side of the conductive layer 110b, to the end portion on the extending portion R_{E} side of the conductive layer 110b.

Such a configuration makes it possible for the conductive layer 110b to be further distanced from the step formed on the lower surface of the terrace portion T3 at the position Y₃₂, and for a withstand voltage between them to be thereby further increased.

### OTHER EMBODIMENTS

That concludes description of the semiconductor memory devices according to the first through third embodiments. However, these configurations are merely exemplifications, and specific configurations may be appropriately adjusted.

For example, in the first embodiment, as described with reference to FIG. 8, the range R₁₂ and the range R₁₆ substantially match, viewed in the Z-direction. However, such a configuration is merely an exemplification, and specific configuration may be appropriately adjusted.

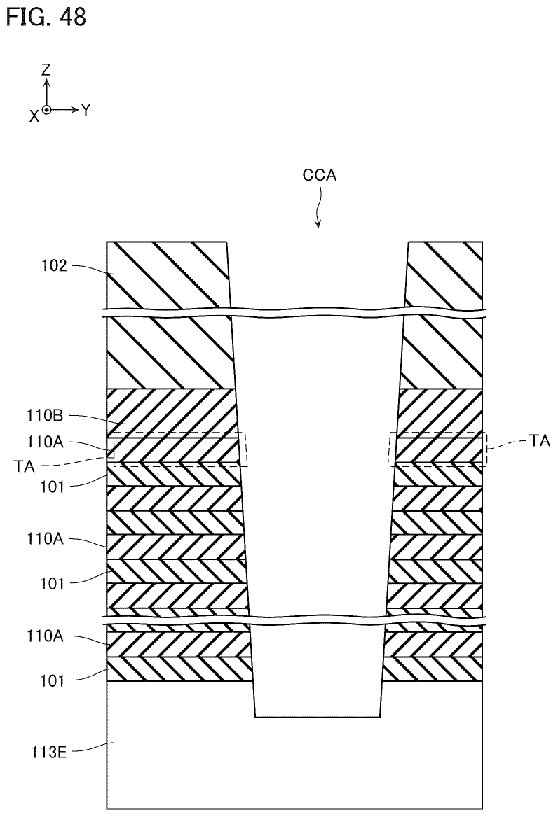

For example, in the step described with reference to FIG. 15, there may be formed a structure of the kind where diameter of the contact hole CCA increases from its lower side to its upper side. FIG. 48 is a schematic cross-sectional view for explaining a method of manufacturing a semiconductor memory device according to another embodiment. FIG. 48 exemplifies such a contact hole CCA.

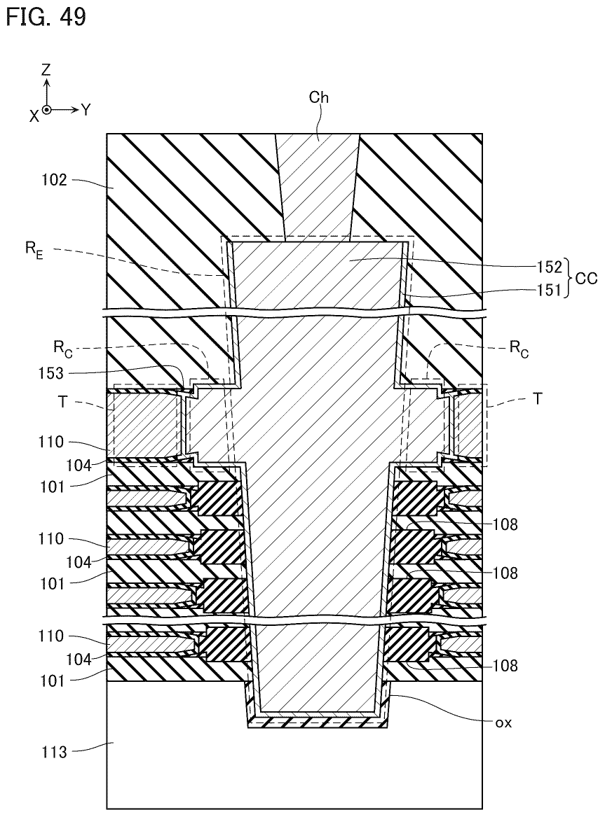

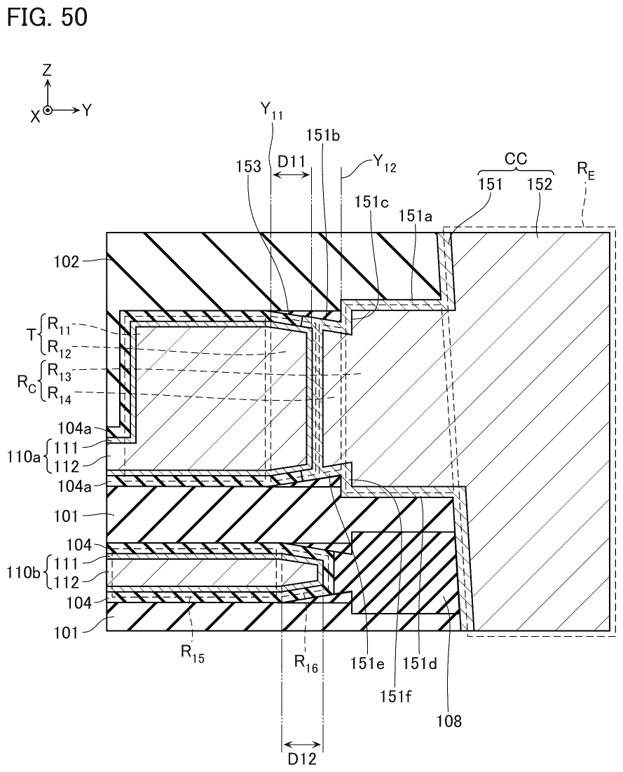

FIGS. 49 and 50 are schematic cross-sectional views showing a part of a configuration of the semiconductor memory device manufactured by such a method. FIG. 50 shows an enlarged part of FIG. 49. Note that although FIG. 50 shows a YZ cross section, a similar structure to in FIG. 50 will be observed, even when a cross section other than a YZ cross section along a central axis of the contact electrode CC (for example, an XZ cross section) is observed.

In the example of FIG. 50, the position Y₁₁ separated by the distance D11 from the contact electrode CC of the conductive layer 110a is provided at an opposite side to the contact electrode CC with respect to the position separated by the distance D12 from the end portion on the contact electrode CC side of the conductive layer 110b, viewed in the Z-direction. Moreover, the contact surface with the contact electrode CC of the conductive layer 110a is provided at the opposite side to the contact electrode CC with respect to the end portion on the contact electrode CC side of the conductive layer 110b, viewed in the Z-direction.

Moreover, in the step described with reference to FIG. 16, for example, etching of a position corresponding to the recessed portion R₁₃A may proceed faster than etching of positions corresponding to the recessed portions 108A. This is because the width in the Z-direction of the recessed portion R₁₃A is greater than the widths in the Z-direction of the recessed portions 108A.

In such a case too, similarly to in the example described with reference to FIGS. 49 and 50, the position Yu separated by the distance D11 from the contact electrode CC of the conductive layer 110a is provided at an opposite side to the contact electrode CC with respect to the position separated by the distance D12 from the end portion on the contact electrode CC side of the conductive layer 110b, viewed in the Z-direction. Moreover, the contact surface with the contact electrode CC of the conductive layer 110a is provided at the opposite side to the contact electrode CC with respect to the end portion on the contact electrode CC side of the conductive layer 110b, viewed in the Z-direction.

In the second embodiment too, the position Y₂₁ separated by the distance D21 from the contact electrode CC2 of the conductive layer 210a of the kind described with reference to FIG. 36 may be provided at an opposite side to the contact electrode CC2 with respect to the position separated by the distance D12 from the end portion on the contact electrode CC2 side of the conductive layer 110b, viewed in the Z-direction.

In the third embodiment too, the position Y₃₁ separated by the distance D31 from the extending portion R_{E} of the terrace portion T3 of the kind described with reference to FIG. 47 may be provided at an opposite side to the extending portion R_{E} with respect to the position separated by the distance D12 from the end portion on the extending portion R_{E} side of the conductive layer 110b, viewed in the Z-direction.

In the other embodiment in these cases too, the step formed on the lower surface of the connecting portion R_{C} of the contact electrode CC (or terrace portions T2, T3) is provided at the contact electrode CC side (an extending portion R_{E} side of the contact electrode CC) with respect to the end portion on the contact electrode CC side of the conductive layer 110b. Such a configuration makes it possible for the end portion on the contact electrode CC side of the conductive layer 110b to be distanced from the above-described step, and for a withstand voltage between them to be thereby increased.

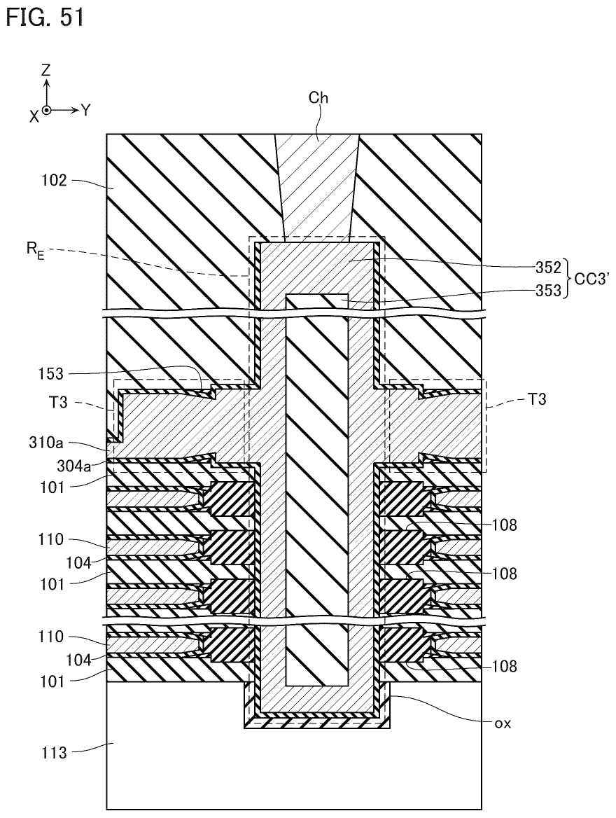

Moreover, materials, film configurations, and so on, of the contact electrodes CC, CC2, CC3 may also be appropriately adjusted. FIG. 51 is a schematic cross-sectional view showing a part of a configuration of a semiconductor memory device according to still another embodiment.

The semiconductor memory device exemplified in FIG. 51 is basically configured similarly to the semiconductor memory device according to the third embodiment. However, the semiconductor memory device exemplified in FIG. 51 comprises a contact electrode CC3′ instead of the contact electrode CC3.

The contact electrode CC3′ is basically configured similarly to the contact electrode CC3. However, the contact electrode CC3′ comprises an insulating film 353 of the likes of silicon oxide (SiO₂), in addition to the barrier conductive film 351 (unillustrated in FIG. 51) and the metal film 352. The insulating film 353 comprises a substantially circular column-like shape extending in the Z-direction. An outer peripheral surface, a lower end, and an upper end of the insulating film 353 are covered by the metal film 352.

The contact electrode CC according to the first embodiment may also comprise a substantially circular column-like configuration of the likes of silicon oxide (SiO₂), with its outer peripheral surface, lower end, and upper end covered by the metal film 152 (FIG. 7), like the insulating film 353.

The contact electrode CC2 according to the second embodiment may also comprise a substantially circular column-like configuration of the likes of silicon oxide (SiO₂), with its outer peripheral surface, lower end, and upper end covered by the metal film 152 (FIG. 35), like the insulating film 353.

### OTHERS

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of memory cells arranged in a first direction;
a plurality of conductive layers arranged in the first direction and connected to the plurality of memory cells; and
a contact electrode including: a connecting portion connected to a first conductive layer among the plurality of conductive layers, at a position in the first direction corresponding to the first conductive layer; and an extending portion extending in the first direction from one side to the other side in the first direction with respect to the first conductive layer, wherein
a thickness in the first direction of the first conductive layer decreases the closer the first conductive layer comes to the contact electrode within a first range from a contact surface with the contact electrode in a second direction intersecting the first direction of the first conductive layer to a position separated by a first distance in the second direction from the contact electrode of the first conductive layer, and
a thickness in the first direction of the connecting portion of the contact electrode decreases the closer the connecting portion comes to the extending portion within a second range from a contact surface with the first conductive layer in the second direction of the connecting portion to a certain position in the second direction between the contact surface and the extending portion of the connecting portion.

2. The semiconductor memory device according to claim 1, further comprising:
a plurality of high-dielectric-constant insulating films each provided on surfaces on one side and the other side in the first direction of the plurality of conductive layers, wherein
high-dielectric-constant insulating films provided on surfaces on one side and the other side in the first direction of the first conductive layer among the plurality of high-dielectric-constant insulating films include end portions on a contact electrode side in the second direction provided within the first range.

3. The semiconductor memory device according to claim 2, wherein
a thickness in the first direction of a structure consisting of the first conductive layer, the connecting portion of the contact electrode, and the high-dielectric-constant insulating films provided on surfaces on one side and the other side in the first direction of the first conductive layer among the plurality of high-dielectric-constant insulating films decreases the closer the structure comes to the extending portion, over a range covering within the first range and within the second range.

4. The semiconductor memory device according to claim 1, wherein
the connecting portion of the contact electrode includes a portion provided within a third range from the certain position in the second direction between the contact surface and the extending portion, to the extending portion, the portion provided within the third range having a thickness in the first direction greater than a thickness in the first direction of a portion provided within the second range of the connecting portion of the contact electrode.

5. The semiconductor memory device according to claim 4, wherein
the contact electrode includes: a barrier conductive film; and a metal film whose outer peripheral surface is covered by the barrier conductive film, and
the barrier conductive film includes:
a first film portion covering a surface on one side in the first direction of the metal film within the second range;
a second film portion covering a surface on one side in the first direction of the metal film within the third range;
a first stepped film portion connected to the first film portion and the second film portion between the first film portion and the second film portion;
a third film portion covering a surface on the other side in the first direction of the metal film within the second range;
a fourth film portion covering a surface on the other side in the first direction of the metal film within the third range; and
a second stepped film portion connected to the third film portion and the fourth film portion between the third film portion and the fourth film portion.

6. The semiconductor memory device according to claim 1, wherein
the connecting portion of the contact electrode includes the certain position in the second direction between the contact surface and the extending portion provided at a side of the extending portion in the second direction with respect to an end portion on a contact electrode side in the second direction of a second conductive layer adjacent to the first conductive layer among the plurality of conductive layers.

7. The semiconductor memory device according to claim 1, wherein
a thickness in the first direction of a second conductive layer adjacent to the first conductive layer among the plurality of conductive layers decreases the closer the second conductive layer comes to the contact electrode within a fourth range from a position separated by a second distance in the second direction from an end portion on a contact electrode side in the second direction of the second conductive layer to the end portion on the contact electrode side in the second direction of the second conductive layer.

8. The semiconductor memory device according to claim 7, further comprising:
a plurality of high-dielectric-constant insulating films each provided on surfaces on one side and the other side in the first direction of the plurality of conductive layers, wherein
high-dielectric-constant insulating films provided on surfaces on one side and the other side in the first direction of the first conductive layer among the plurality of high-dielectric-constant insulating films include end portions on a contact electrode side in the second direction provided within the fourth range in the second direction.

9. The semiconductor memory device according to claim 1, wherein
the first conductive layer includes the contact surface with the contact electrode in the second direction provided at an opposite side to the extending portion in the second direction with respect to an end portion on a contact electrode side in the second direction of a second conductive layer adjacent to the first conductive layer among the plurality of conductive layers.

10. A semiconductor memory device comprising:
a plurality of memory cells arranged in a first direction;
a plurality of conductive layers arranged in the first direction and connected to the plurality of memory cells; and
a contact electrode connected to a first conductive layer among the plurality of conductive layers, and extending in the first direction from one side to the other side in the first direction with respect to the first conductive layer, wherein
a thickness in the first direction of the first conductive layer decreases the closer the first conductive layer comes to the contact electrode within a first certain range from a first position separated by a first certain distance in a second direction intersecting the first direction from the contact electrode to a second position between the first position and the contact electrode in the second direction, and
the first conductive layer includes a portion provided within a second certain range from a contact surface with the contact electrode to the second position in the second direction, the portion provided within the second certain range having a thickness in the first direction greater than a thickness in the first direction of a portion provided within the first certain range of the first conductive layer.

11. The semiconductor memory device according to claim 10, further comprising:
a plurality of high-dielectric-constant insulating films each provided on surfaces on one side and the other side in the first direction of the plurality of conductive layers, wherein
high-dielectric-constant insulating films provided on surfaces on one side and the other side in the first direction of the first conductive layer among the plurality of high-dielectric-constant insulating films include end portions on a contact electrode side in the second direction provided within the second certain range.

12. The semiconductor memory device according to claim 10, wherein
a thickness in the first direction of a second conductive layer adjacent to the first conductive layer among the plurality of conductive layers decreases the closer the second conductive layer comes to the contact electrode within a range from a position separated by a second certain distance in the second direction from an end portion on a contact electrode side in the second direction of the second conductive layer to the end portion on the contact electrode side in the second direction of the second conductive layer.

13. The semiconductor memory device according to claim 10, wherein
the first conductive layer includes the contact surface with the contact electrode in the second direction provided at a side of a portion where the contact electrode extends in the first direction in the second direction with respect to an end portion on a contact electrode side in the second direction of a second conductive layer adjacent to the first conductive layer among the plurality of conductive layers.

14. The semiconductor memory device according to claim 10, wherein
the second position is provided at a side of a portion where the contact electrode extends in the first direction in the second direction with respect to an end portion on a contact electrode side in the second direction of a second conductive layer adjacent to the first conductive layer among the plurality of conductive layers.

15. A semiconductor memory device comprising:
a plurality of memory cells arranged in a first direction;
a plurality of conductive layers arranged in the first direction and connected to the plurality of memory cells; and
a contact electrode, which is provided in a terrace region where a first conductive layer among the plurality of conductive layers does not overlap another conductive layer among the plurality of conductive layers viewed from one side in the first direction, which is connected to the first conductive layer or is continuous with the first conductive layer, and which includes an extending portion extending in the first direction from the one side to the other side in the first direction with respect to the first conductive layer, wherein
a thickness in the first direction in the terrace region of a conductive member consisting of the first conductive layer and the contact electrode decreases the closer the conductive member comes to the extending portion within a first region from a first certain position separated by a first certain distance in a second direction intersecting the first direction from the extending portion to a second certain position between the first certain position and the extending portion,
the conductive member includes a portion provided within a second region from the extending portion to the second certain position, the portion provided within the second region having a thickness in the first direction greater than a thickness in the first direction of a portion provided within the first region of the conductive member, and
the second certain position is provided at an extending portion side in the second direction with respect to an end portion on the extending portion side in the second direction of a second conductive layer adjacent to the first conductive layer among the plurality of conductive layers.

16. The semiconductor memory device according to claim 15, wherein
the contact electrode is connected to the first conductive layer, and
the first conductive layer includes a contact surface with the contact electrode provided within the first region or within the second region.

17. The semiconductor memory device according to claim 15, wherein
the contact electrode is continuous with the first conductive layer,
the contact electrode includes: a first barrier conductive film; and a first metal film whose outer peripheral surface is covered by the first barrier conductive film,
the first conductive layer includes: a second barrier conductive film; and a second metal film whose surfaces on one side and the other side in the first direction are covered by the second barrier conductive film,
the first barrier conductive film is continuous with the second barrier conductive film, and
the first metal film is continuous with the second metal film.

18. The semiconductor memory device according to claim 17, wherein
the second barrier conductive film includes:
a first film portion covering a surface on the one side in the first direction of the second metal film within the first region;
a second film portion covering a surface on the one side in the first direction of the second metal film within the second region;
a first stepped film portion connected to the first film portion and the second film portion between the first film portion and the second film portion;
a third film portion covering a surface on the other side in the first direction of the second metal film within the first region;
a fourth film portion covering a surface on the other side in the first direction of the second metal film within the second region; and
a second stepped film portion connected to the third film portion and the fourth film portion between the third film portion and the fourth film portion.

19. The semiconductor memory device according to claim 15, further comprising:
a plurality of high-dielectric-constant insulating films each provided on surfaces on one side and the other side in the first direction of the plurality of conductive layers, wherein
the contact electrode is continuous with the first conductive layer, and
high-dielectric-constant insulating films provided on surfaces on one side and the other side in the first direction of the first conductive layer among the plurality of high-dielectric-constant insulating films cover an outer peripheral surface of the extending portion.

20. The semiconductor memory device according to claim 15, wherein
a thickness in the first direction of the second conductive layer decreases the closer the second conductive layer comes to the extending portion within a range from a position separated by a second certain distance in the second direction from the end portion on the extending portion side in the second direction of the second conductive layer to the end portion on the extending portion side in the second direction of the second conductive layer.
